(19) United States
(12) Patent Application Publication
(10) Pub. No.: US 2026/0101780 A1
(43) Pub. Date: Apr. 9, 2026

(54) COMPOSITE PACKAGES FOR ENHANCING THERMAL DISSIPATION AND METHODS FOR FORMING THE SAME

(71) Applicant: Taiwan Semiconductor Manufacturing Company Limited, Hsinchu (TW)

(72) Inventors: Kai-Fung Chang, Taipei City (TW); Li-Hui Cheng, New Taipei City (TW); Ying-Ching Shih, Hsinchu City (TW)

(21) Appl. No.: 18/822,401

(22) Filed: Sep. 2, 2024

(51) Int. Cl. H01L 23/00; H01L 21/56; H01L 23/16; H01L 23/31; H01L 23/498; H01L 25/18; H05K 1/18

(52) U.S. Cl. CPC H10W 70/65; H10W 74/016; H10W 74/114; H10W 90/401; H05K 1/181; H05K 2201/10734; H10W 72/01235; H10W 72/01253; H10W 72/0198; H10W 72/227; H10W 72/248; H10W 74/15; H10W 76/40; H10W 90/00; H10W 90/724; H10W 90/734

(57) ABSTRACT

A composite package may have a feature for enhancing thermal dissipation. The feature may include an array of metal pillar located on a backside a semiconductor die. Alternatively, the feature may include a cavity, to which a backside surface of a semiconductor die is exposed and which is laterally surrounded by a portion of a molding compound die frame.

### BACKGROUND

Integrating a thick semiconductor die such as a DRAM die with a thin semiconductor die such as a system-on-chip (SoC) die presents challenges due to the disparity in their thicknesses. Particularly, coverage of a backside surface of a thinner semiconductor die with a molding compound material degrades thermal dissipation from the semiconductor die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A-1J are sequential vertical cross-sectional views of a first intermediate structure during formation of an assembly comprising a first semiconductor die, an array of metal pillars, and a backside molding compound frame according to a first embodiment of the present disclosure.

FIG. 2A is a vertical cross-sectional view of an interposer according to an embodiment of the present disclosure.

FIG. 2B is a top-down view of the interposer of FIG. 2A. The vertical plane A-A′ is the cut plane of the vertical cross-sectional view of FIG. 2A.

FIG. 3A-3I are sequential vertical cross-sectional views of a first embodiment structure during formation of a bonded assembly including an interposer and a plurality of semiconductor dies according to the first embodiment of the present disclosure.

FIG. 4A-4C are sequential vertical cross-sectional views of a second intermediate structure during formation of an assembly comprising a first semiconductor die, an array of metal pillars, and a backside molding compound frame according to a second embodiment of the present disclosure.

FIG. 5A-5E are sequential vertical cross-sectional views of a second embodiment structure during formation of a bonded assembly including an interposer and a plurality of semiconductor dies according to the second embodiment of the present disclosure.

FIG. 6A-6C are sequential vertical cross-sectional views of a third intermediate structure during formation of an assembly comprising a first semiconductor die, an array of metal pillars, and a backside molding compound frame according to a third embodiment of the present disclosure.

FIG. 7A- 7K are sequential vertical cross-sectional views of a third embodiment structure during formation of a bonded assembly including an interposer and a plurality of semiconductor dies according to the third embodiment of the present disclosure. FIG. 7L is a top-down view of the third exemplary structures of FIG. 7K. FIG. 7M is a vertical cross-sectional view of a first alternative configuration of the third embodiment structure according to the third embodiment of the present disclosure.

FIG. 7N is a second alternative configuration of the third embodiment structure according to the third embodiment of the present disclosure.

FIG. 8 is a first flowchart illustrating steps for forming a device structure according to an embodiment of the present disclosure.

FIG. 9 is a second flowchart illustrating steps for forming a device structure according to an embodiment of the present disclosure.

### DETAILED DESCRIPTION

The following disclosure provides many different embodiments, or examples, for implementing different features of the provided subject matter. Specific examples of components and arrangements are described below to facilitate understanding of the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Embodiments of the present disclosure are directed to methods of forming composite packages including semiconductor devices. In one embodiment, an array of metal pillars may be formed on the backside of a semiconductor die, and may be used as a stopper structure during formation of a multi-die molding compound die frame. In another embodiment, a die attachment film may be attached to the backside of a semiconductor die, and may be used to provide a reference structure for controlling the height of a multi-die molding compound die frame. Embodiments of the present disclosure may be used to enhance the structural integrity and thermal management of semiconductor packages. The various aspects of the present disclosure are now described with reference to accompanying drawings.

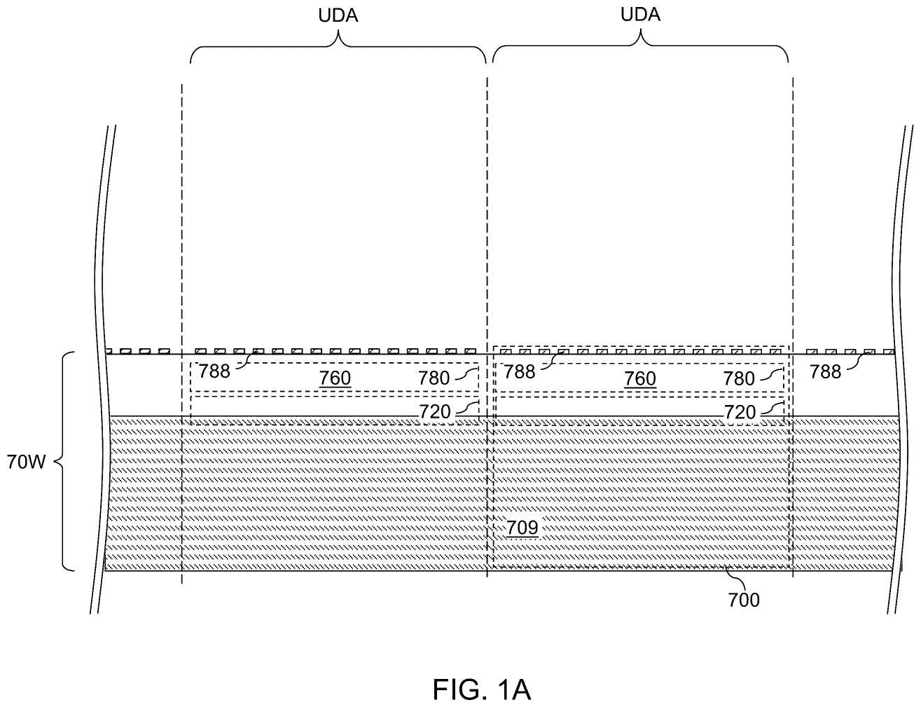

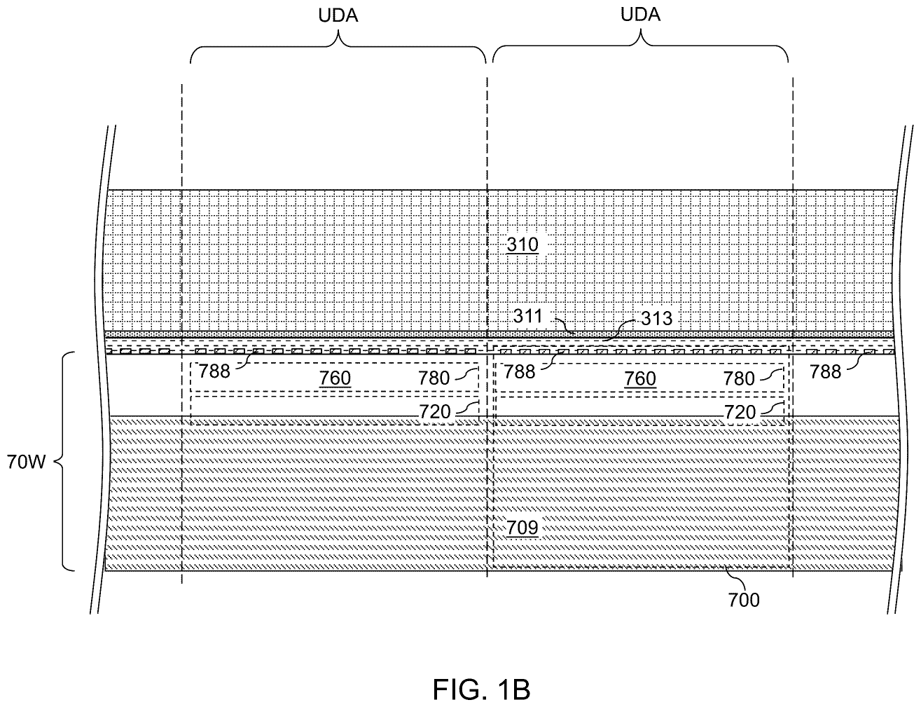

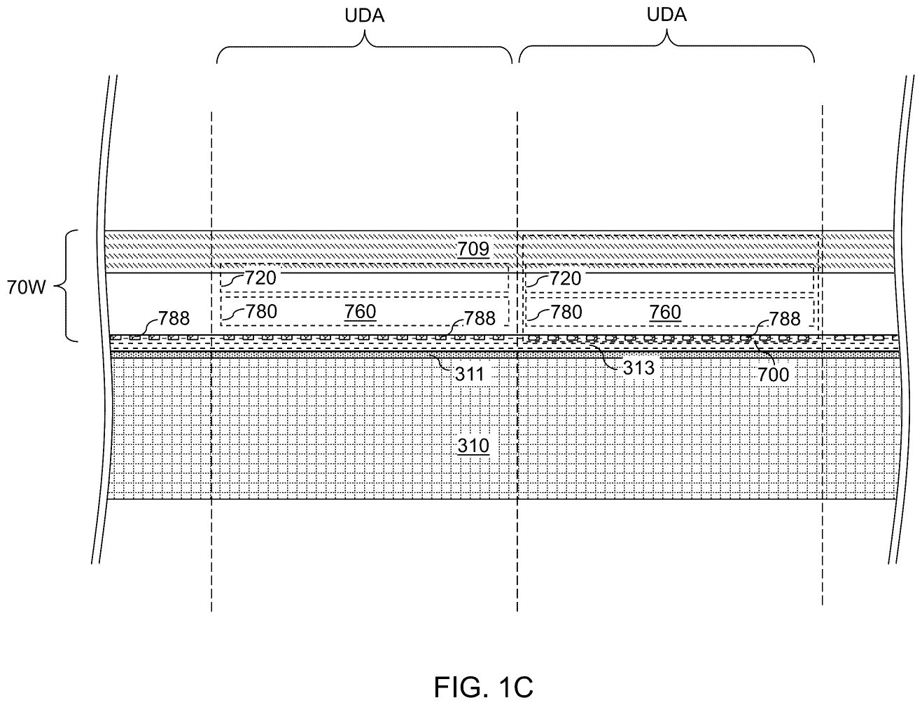

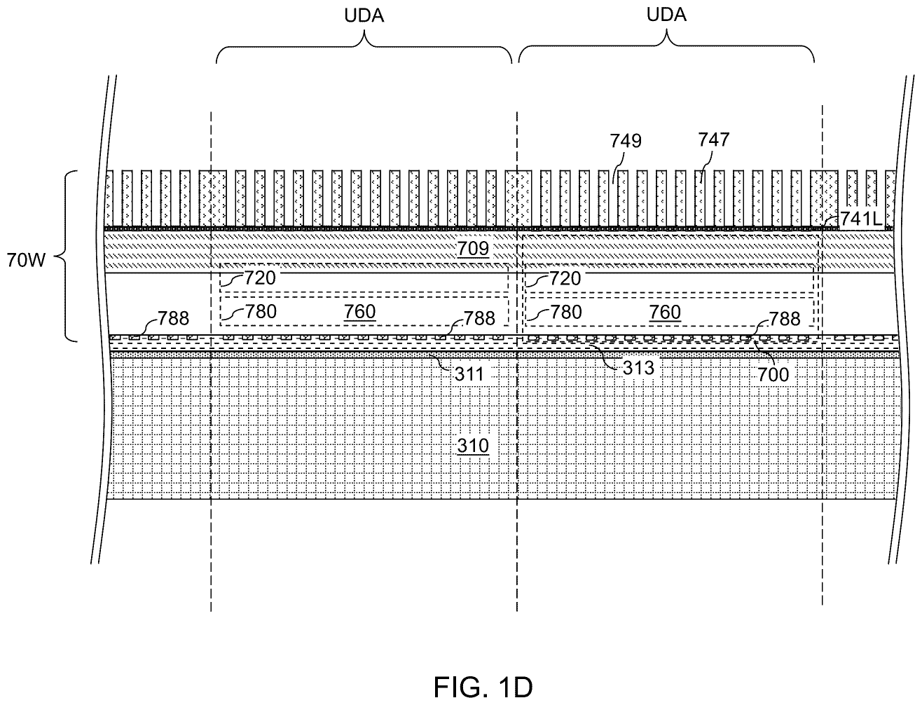

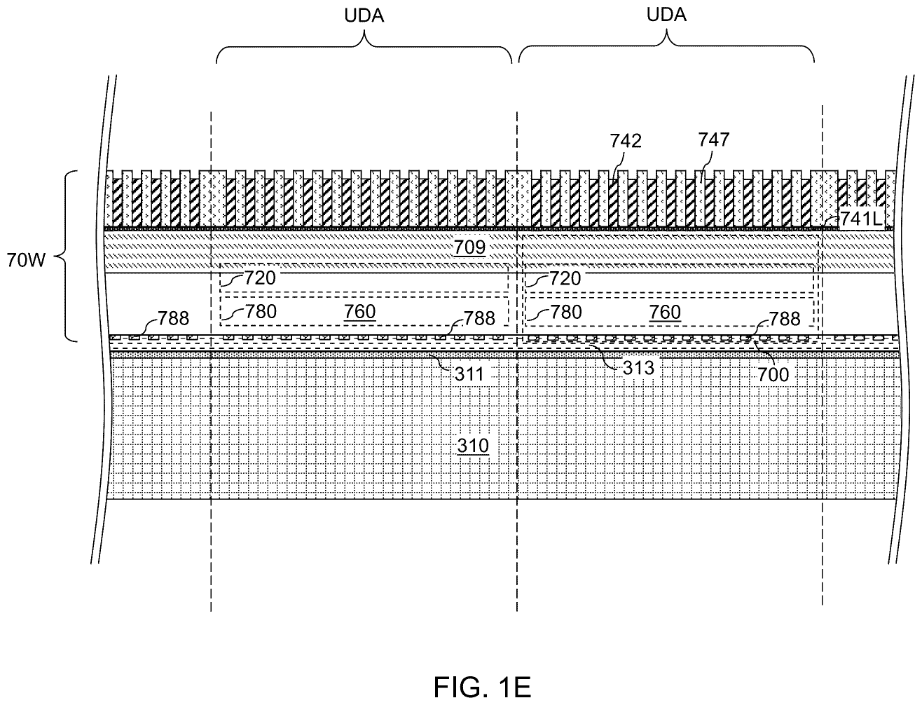

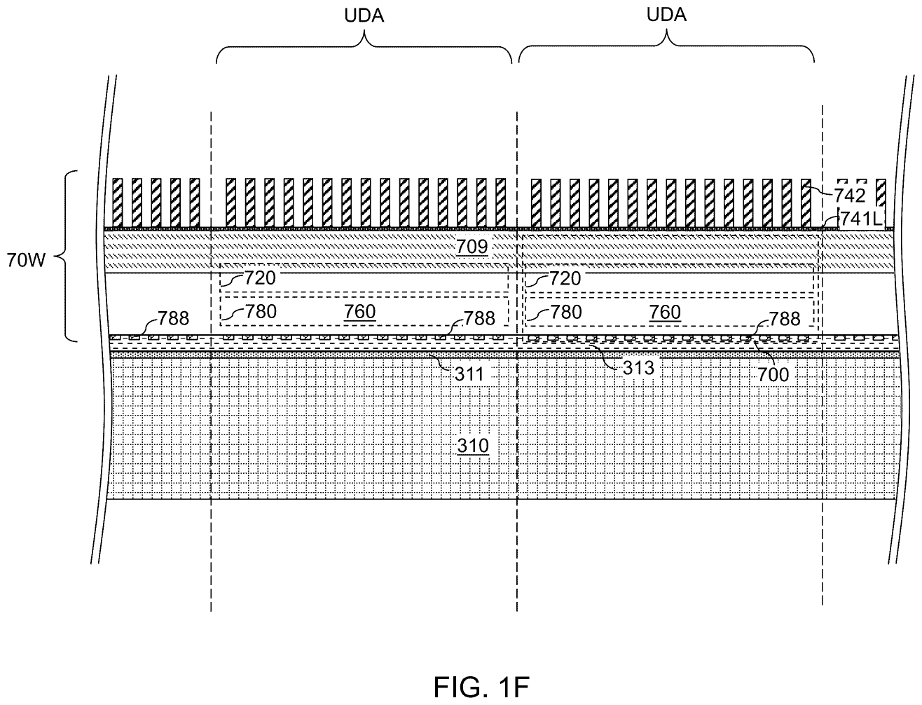

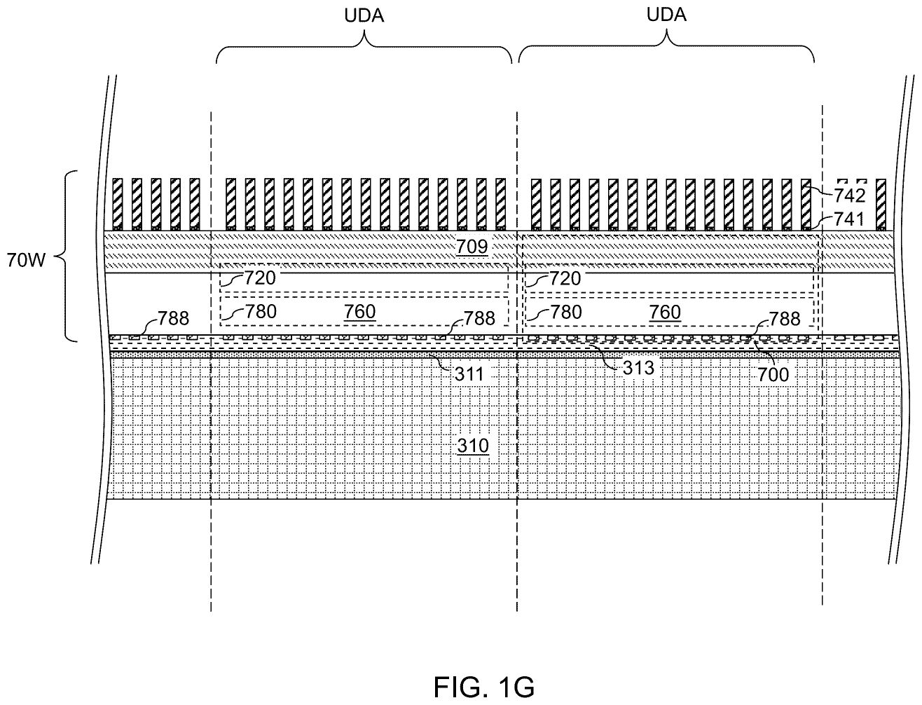

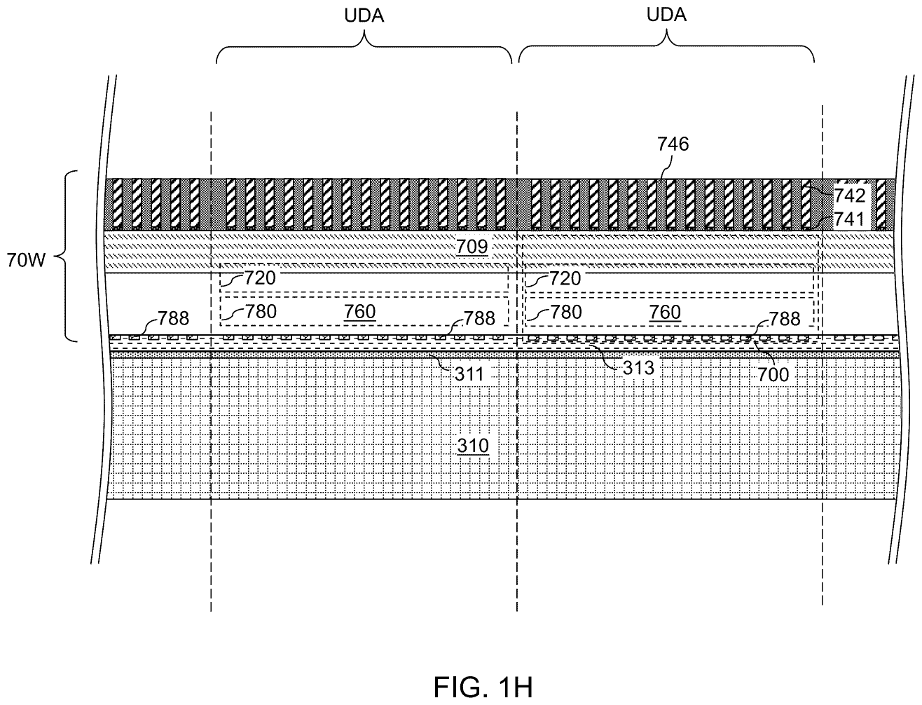

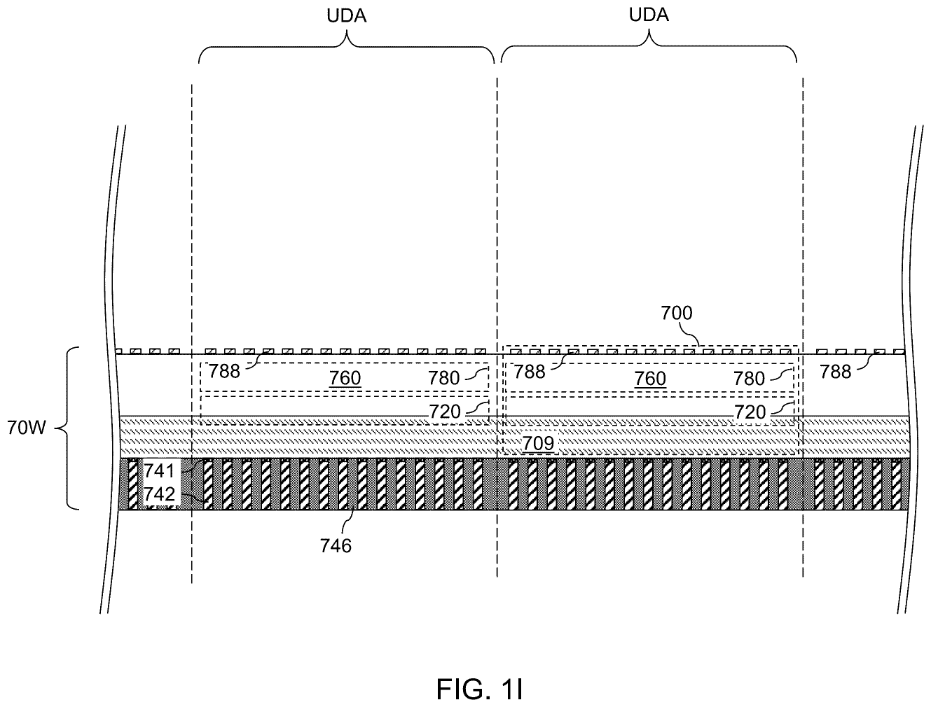

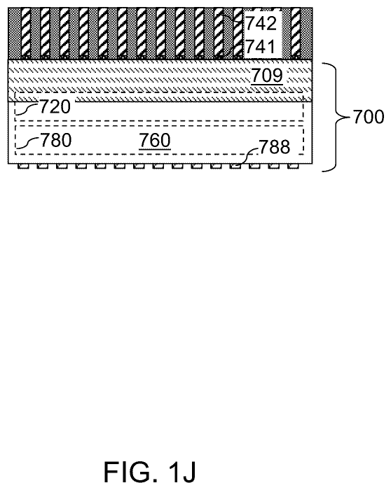

FIG. 1A-1J are sequential vertical cross-sectional views of a first intermediate structure during formation of an assembly comprising a first semiconductor die 700, an array of metal pillars 742, and a backside molding compound frame 746 according to a first embodiment of the present disclosure.

Referring to FIG. 1A, a device wafer 70W including a two-dimensional array of first semiconductor dies 700 is illustrated. The area of each first semiconductor die 700 is herein referred to as a unit die area UDA. It is understood that only a segment of the device wafer 70W is illustrated in a vertical cross-sectional view in FIG. 1A and subsequent drawings up to FIG. 1I. Each of the first semiconductor dies 700 comprises a respective portion of a semiconductor substrate 709. The semiconductor substrate 709 may comprise any type of semiconductor substrate on which semiconductor devices 720 may be formed. For example, the semiconductor substrate 709 may comprise a commercially available single crystalline silicon wafer. Alternatively, the semiconductor substrate 709 may comprise a polycrystalline semiconductor wafer or a compound semiconductor material wafer. The thickness of the semiconductor substrate 709 may be in a range from 60 microns to 1,000 microns, although lesser and greater thicknesses may also be used.

Each of the first semiconductor dies 700 comprises semiconductor devices 720 formed on the respective portion of the semiconductor substrate 709. The semiconductor devices 720 may comprise any type of semiconductor device known in the art. For example, the semiconductor devices 720 may comprise a central processing unit, a graphic processing unit, a neural processing unit, a memory array, or any other type of integrated circuit. As such, each first semiconductor die 700 may comprise any of a logic die, a system-on-chip (SoC) die, a memory die, a sensor die, a communication die, an optical die, etc.

Each of the first semiconductor dies 700 comprises metal interconnect structures 780 formed within dielectric material layers 760. The metal interconnect structures 780 provide electrical connections to and from the various semiconductor devices 720 within a respective first semiconductor die 700. Each of the first semiconductor dies 700 comprises first metal bonding pads 788 located on the most distal layer selected from the dielectric material layers 760 and electrically connected to the semiconductor devices 720 through the metal interconnect structures 780. The first metal bonding pads 788 may be configured for solder-mediated bonding or metal-to-metal bonding. A solder-mediated bonding refers to a bonding process where solder material is used to create a mechanical and electrical connection between bonding pads. Exemplary solder-mediated bondings include chip connection (C2) bonding using microbumps and controlled collapse chip connection (C4) bonding using C4 bonding pads. Metal-to-metal bonding refers to a direct bonding process where the bonding pads are joined without the use of solder, typically through techniques such as thermocompression or direct bonding. Exemplary metal-to-metal bondings include copper-to-copper (Cu—Cu) bonding and aluminum-to-aluminum (Al-Al) bonding.

Referring to FIG. 1B, an adhesive layer 313 may be applied to the front side of a device wafer 70W. The adhesive layer 313 may comprise any adhesive material known in the art. A carrier wafer 310 is provided, which may comprise any of a glass wafer, a silicon wafer, a metal wafer, etc. The material and the thickness of the carrier wafer 310 may be selected such that the carrier wafer 310 provides sufficient mechanical support during subsequent backside thinning of the semiconductor substrate 709. In one embodiment, a wafer attachment film 311 may be attached to a planar horizontal surface of the carrier wafer 310 and may be subsequently attached to the adhesive layer 313. The wafer attachment film 311 may comprise a film including suitable wafer attachment material such as polyimide, silicone, or epoxy, as known in the art. The wafer attachment film 311 may comprise a die attachment film as known in the art. For example, the wafer attachment film 311 may comprise a polyimide-based film, a silicone-based film, or an epoxy-based film. In one embodiment, the wafer attachment film 311 may comprise an ultraviolet-sensitive adhesive, and the carrier wafer 310 may comprise a transparent material such as glass. The carrier wafer 310 may be attached to the device wafer 70W with the adhesive layer 313 and the wafer attachment film 311 therebetween. Thus, the device wafer 70W may be attached to the carrier wafer 310 such that the backside surface of the device wafer 70W is physically exposed.

Referring to FIG. 1C, a backside thinning process may be performed to thin the backside of the semiconductor substrate 709. For example, the backside of the semiconductor substrate 709 may be removed by performing at least one removal process such as grinding, polishing, an anisotropic etch process, and/or an isotropic etch process. In one embodiment, a chemical mechanical polishing process and a surface clean process may be performed as final processing steps of the backside thinning process. The thickness of the semiconductor substrate 709 after the thinning process may be in a range from 5 microns to 200 microns, such as from 10 microns to 60 microns, although lesser and greater thicknesses may also be used. The thickness of the device wafer 70W may be in a range from 10 microns to 300 microns, such as from 20 microns to 200 microns, although lesser and greater thicknesses may also be used.

Referring to FIG. 1D, a metallic seed layer 741L may be deposited directly on a backside horizontal surface of the device wafer 70W, i.e., on the physically exposed backside surfaces of the first semiconductor dies 700. The metallic seed layer 741L comprises a metallic seed material for subsequently electroplating a metallic material thereupon. The metallic seed layer 741L may comprise copper, palladium, nickel, titanium (Ti), tantalum (Ta), titanium nitride (TiN), or tantalum nitride (TaN). For example, the metallic seed layer 741L may comprise a layer stack including a copper seed layer followed by a palladium barrier layer or a titanium nitride seed layer followed by a tantalum nitride barrier layer. The metallic seed layer 741L may be deposited by sputtering, atomic layer deposition (ALD), chemical vapor deposition (CVD), and/or physical vapor deposition (PVD). The thickness of the metallic seed layer 741L may be in a range from 10 nm to 200 nm, although lesser and greater thicknesses may also be used. The metallic seed layer 741L is incorporated into the device wafer 70W.

A plating matrix layer 747 including arrays of pillar-shaped cavities 749 may be formed over the metallic seed layer 741L. The plating matrix layer 747 comprises a material that may be used as a plating matrix for a subsequent electroplating process. For example, the plating matrix layer 747 may comprise a photosensitive polymer material such as polyimide, an epoxy-based negative photoresist (such as SU-8), benzocyclobutene (BCB), etc. The thickness of the plating matrix layer 747 may be in a range from 5 microns to 120 microns, such as from 20 microns to 100 microns, although lesser and greater thicknesses may also be used. The plating matrix layer 747 may be initially formed as a blanket material layer without any pattern therein, and may be lithographically patterned to form a pattern of arrays of cylindrical cavities. The arrays of cylindrical cavities are herein referred to as arrays of pillar-shaped cavities 749. Each array of pillar-shaped cavities 749 may be formed on the backside of a respective one of the first semiconductor dies 700. The lateral dimension of each pillar-shaped cavity 749 may be in a range from 5 microns to 200 microns, such as from 10 microns to 100 microns, although lesser and greater lateral dimensions may also be used. The pitch of each array of pillar-shaped cavities 749 may be in a range from 10 microns to 400 microns, such as from 20 microns to 200 microns, although lesser and greater pitches may also be used. In one embodiment, each array of pillar-shaped cavities 749 may be formed as a rectangular periodic array or as a hexagonal periodic array.

Referring to FIG. 1E, an electroplating process may be performed to electroplate a metal within the volumes of the arrays of pillar-shaped cavities 749. For example, the combination of the carrier wafer 310 and the device wafer 70W with the plating matrix layer 747 thereupon may be immersed in an electrolyte bath containing metal ions. An electric current may be flowed between an anode and the device wafer 70W, which acts as the cathode, to deposit the metal on the physically exposed surfaces of the metallic seed layer 741L within the arrays of pillar-shaped cavities 749. Materials that may be electroplated within the array of pillar-shaped cavities 749 include, but are not limited to, copper, cobalt tungsten phosphorus (CoWP), cobalt tungsten (CoW), nickel, gold, and silver. In one embodiment, the electroplating process may comprise a copper electroplating process, in which the combination of the carrier wafer 310 and the device wafer 70W is submerged into a copper sulfate bath, and an electrical current is flowed in the copper sulfate bath to deposit copper ions onto the physically exposed surfaces of the metallic seed layer 741L and to subsequently grow copper portions within the volumes of the arrays of pillar-shaped cavities 749.

An array of metal pillars 742 is formed within each array of pillar-shaped cavities 749 by the electroplating process. Thus, an array of metal pillars 742 may be formed on the backside of each first semiconductor die 700. The duration of the electroplating process may be selected such that the height of the array of metal pillars 742 is not greater than the thickness of the plating matrix layer 747. The height of the metal pillars 742 may be in a range from 3 microns to 100 microns, such as from 10 microns to 60 microns, although lesser and greater heights may also be used. Each array of metal pillars 742 may be attached to the backside surface of the device wafer 70W, i.e., to the backside surface of a respective one of the first semiconductor dies 700, through the metallic seed layer 741L. The arrays of metal pillars 742 may be incorporated into the device wafer 70W.

Referring to FIG. 1F, the plating matrix layer 747 may be removed selectively to the arrays of metal pillars 742 and the metallic seed layer 741L. For example, the removal process may involve using a chemical etchant that dissolves the material of the plating matrix layer 747 without affecting the metal pillars 742 or the metallic seed layer 741L. In an illustrative example, a solvent bath containing a solution such as EKC162 at an elevated temperature (typically around 60 degrees Celsius) may be used. Any remaining residue of the plating matrix layer 747 may be cleaned using a mild plasma etch or a deionized water rinse to ensure complete removal of the plating matrix material while preserving the integrity of the metal pillars 742 and the metallic seed layer 741L.

Referring to FIG. 1G, a selective isotropic etch process may be performed to remove portions of the metallic seed layer 741L that are not covered by the arrays of metal pillars 742. For example, an isotropic wet etching process may be performed to remove portions of the metallic seed layer 741L that are not masked by the arrays of metal pillars 742 without significantly etching the metal pillars 742. Exemplary solutions that may be used for the isotropic wet etch process include, but are not limited to, buffered hydrofluoric acid (BHF), sulfuric acid, and a ferric sulfate-based solution. Remaining portions of the metallic seed layer 741L after the selective isotropic etch process comprise metallic seed plates 741. Each array of metal pillars 742 may be attached to the backside of a respective first semiconductor die 700 by a respective array of metallic seed plates 741.

Referring to FIG. 1H, a molding compound material may be applied around the array of metal pillars 742. The molding compound material includes an epoxy-containing compound that may be hardened (i.e., cured) to provide a dielectric material portion having sufficient stiffness and mechanical strength. The molding compound material may include epoxy resin, hardener, silica (as a filler material), and other additives. The molding compound material may be provided in a liquid form or in a solid form depending on the viscosity and flowability. Liquid molding compound material typically provides better handling, good flowability, less voids, better fill, and less flow marks. Solid molding compound material typically provides less cure shrinkage, better stand-off, and less die drift. A high filler content (such as 85% in weight) within a molding compound material may shorten the time in mold, lower the mold shrinkage, and reduce the mold warpage. Uniform filler size distribution in the molding compound material may reduce flow marks, and may enhance flowability.

The molding compound material may be cured, for example, by performing a thermal cure process at an elevated temperature, which may be in a range from 165 degrees Celsius to 185 degrees Celsius. Excess portions of the molding compound material may be removed from above the horizontal plane including the top surfaces of the metal pillars 742 by performing a planarization process. For example, a chemical mechanical polishing process may be performed to remove the excess portions of the molding compound material from above the horizontal plane including the top surfaces of the metal pillars 742. The remaining portion of the molding compound material constitutes a molding compound matrix that laterally surrounds the array of metal pillars 742. Each portion of the molding compound matrix located within the area of a respective unit die area UDA constitutes a backside molding compound frame 746. Thus, each backside molding compound frame 746 laterally surrounds a respective array of metal pillars 742, and is formed directly on the backside horizontal surface of a respective first semiconductor die 700.

Generally, a backside molding compound frame 746 may be formed directly on each array of metal pillars 742 after removal of the plating matrix layer 747. Within each unit die area UDA, an array of metallic seed plates 741 may be located between an array of metal pillars 742 and a backside surface of a first semiconductor die 700. In one embodiment, the backside molding compound frame 746 is in direct contact with a backside surface of the first semiconductor die 700. The backside molding compound frames 746 are incorporated into the device wafer 70W.

Referring to FIG. 1I, the carrier wafer 310 may be detached from the device wafer 70W by deactivating the wafer attachment film 311. In instances in which the wafer attachment film 311 comprises an ultraviolet-decomposable adhesive material and if the carrier wafer 310 comprises a transparent material, the wafer attachment film 311 may be decomposed by ultraviolet irradiation through the carrier wafer 310. If the wafer attachment film 311 comprises a thermally-decomposable adhesive material, a thermal anneal at an elevated temperature (which may be in a range from 200 degrees Celsius to 250 degrees Celsius) may be used to decompose the wafer attachment film 311.

Subsequently, the adhesive layer 313 may be removed selectively to the materials of the first semiconductor dies 700, the metal pillars 742, and the backside molding compound frame 746. For example, the adhesive layer 313 may be removed by performing a selective chemical etching process that removes the adhesive material of the adhesive layer 313 selectively to the materials of the first semiconductor dies 700, the metal pillars 742, and the backside molding compound frame 746. In an illustrative example, a wet etch process using a solvent such as acetone or an oxygen plasma etch process may be performed to effectively dissolve or decompose the adhesive layer 313 without removing the materials of the first semiconductor dies 700, the metal pillars 742, and the backside molding compound frame 746. A suitable surface clean process may be subsequently performed to remove any residual material.

Referring to FIG. 1J, the device wafer 70W may be diced along dicing channels. The assembly of the two-dimensional array of first semiconductor dies 700, the arrays of metallic seed plates 741, the arrays of metal pillars 742, and the molding compound matrix (which comprises a two-dimensional array of backside molding compound frames 746) may be diced into discrete diced portions. Each discrete diced portion comprises an assembly of a first semiconductor die 700, an array of metallic seed plates 741, an array of metal pillars 742, and a backside molding compound frame 746.

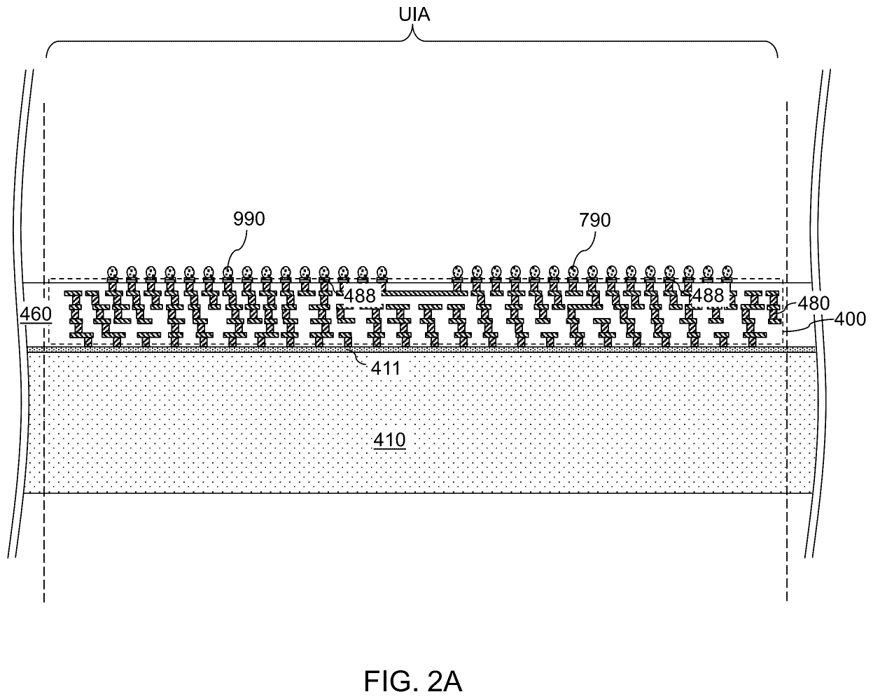

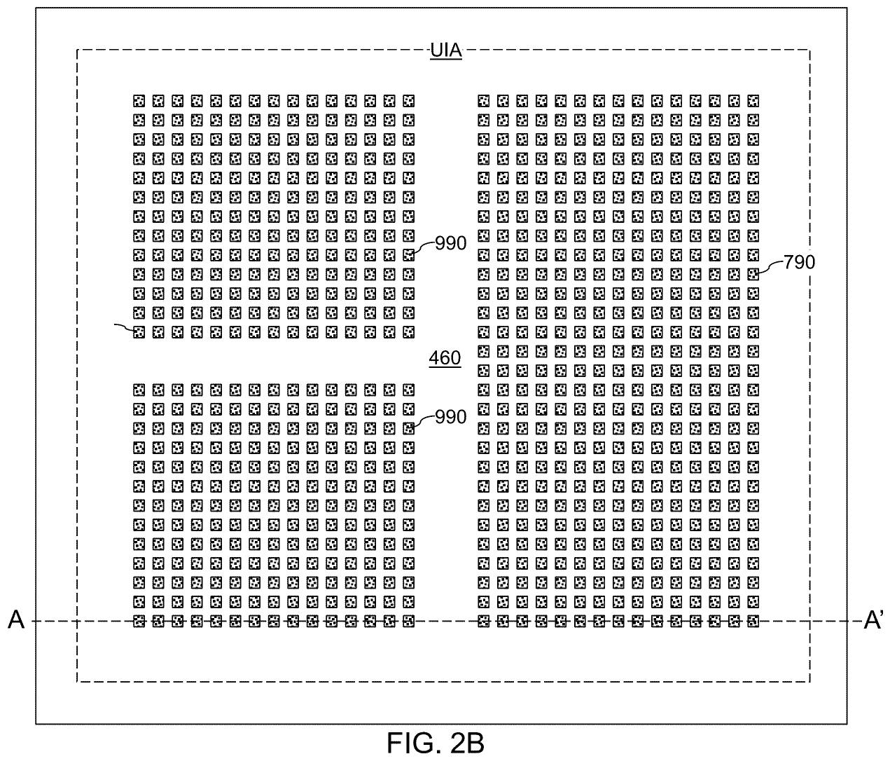

Referring to FIGS. 2A and 2B, a unit interposer area UIA of an array of interposers 400 formed on a handle wafer 410 is illustrated. The handle wafer 410 may comprise any wafer that may be used to provide structural support during manufacture of the array of interposers 400. For example, the handle wafer 410 may comprise a glass wafer, a semiconductor wafer, or a metallic wafer. The thickness of the handle wafer 410 may be in a range from 300 microns to 1 mm, although lesser and greater thicknesses may also be used. An adhesive layer 411 may be applied on the top surface of the handle wafer 410. Redistribution dielectric layers 460 and redistribution wiring interconnects 480 may be formed over the adhesive layer 411 to form a redistribution structure (460, 480). Die-side interposer bonding pads 488 may be formed on a topmost subset of the redistribution wiring interconnects 480.

The redistribution dielectric layers 460 may comprise dielectric polymer materials such as polyimide (PI), benzocyclobutene (BCB), or polybenzobisoxazole (PBO). Each of the redistribution dielectric layers 460 may be formed by spin coating and drying of the respective dielectric polymer material. The thickness of each redistribution dielectric layer 460 may be in a range from 2 microns to 40 microns, such as from 4 microns to 20 microns. Each of the redistribution dielectric layers 460 may be patterned using a respective combination of a lithographic patterning process and an anisotropic etch process. Each of the redistribution wiring interconnects 480 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the redistribution wiring interconnects 480 may include copper, nickel, or copper and nickel. The thickness of the metallic fill material that is deposited for each redistribution wiring interconnect 480 may be in a range from 2 microns to 40 microns, such as from 4 microns to 10 microns, although lesser or greater thicknesses may also be used. The total number of levels of the redistribution wiring interconnects 480 may be in a range from 1 to 10, although a greater number of levels may also be used.

The die-side interposer bonding pads 488 may comprise bump structures that are configured for chip connection (C2) bonding (i.e., microbump structures) or for controlled collapse chip connection (C4) bonding (i.e., C4 bonding pads). In one embodiment, the die-side interposer bonding pads 488 may have a thickness in a range from 5 microns to 100 microns, although lesser or greater thicknesses may also be used. In one embodiment, the die-side interposer bonding pads 488 may be formed as an array of microbumps (such as copper pillars) having a lateral dimension in a range from 10 microns to 50 microns, and having a pitch in a range from 20 microns to 100 microns.

In one embodiment, the die-side interposer bonding pads 488 may be arranged as a plurality of arrays of die-side interposer bonding pads 488 configured for bonding with a plurality of semiconductor dies. For example, the die-side interposer bonding pads 488 may comprise a first array of die-side interposer bonding pads 488 arranged in a pattern that is a mirror image pattern of the first metal bonding pads 788 of a first semiconductor die 700 provided at the processing steps of FIG. 1J, and at least one second array of die-side interposer bonding pads 488 arranged in a mirror image pattern of a respective second semiconductor die to be subsequently attached to the interposer 400. An array of first solder material portions 790 may be attached to the first array of die-side interposer bonding pads 488, and an array of second solder material portions 990 may be attached to each second array of die-side interposer bonding pads 488.

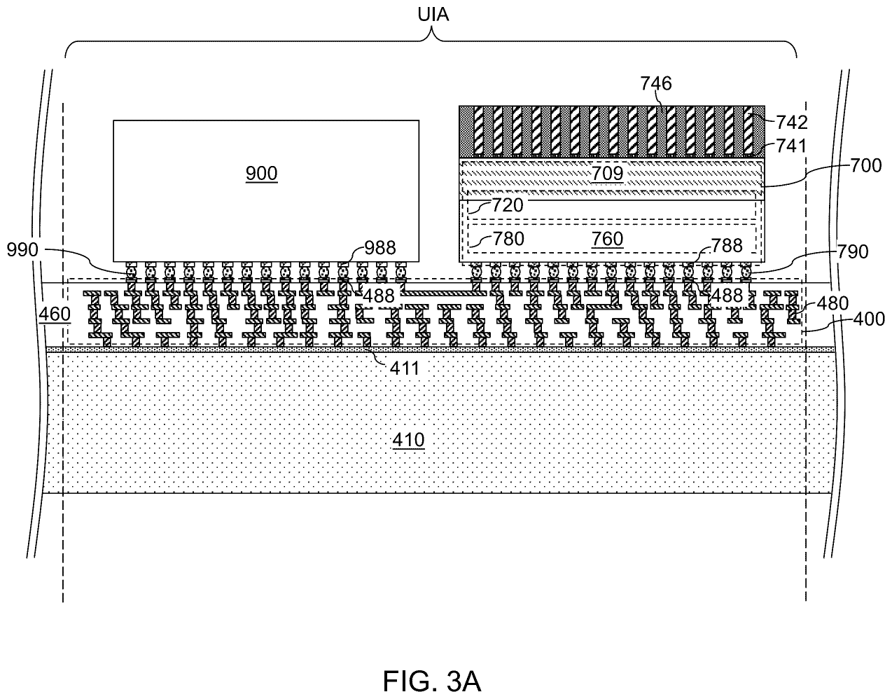

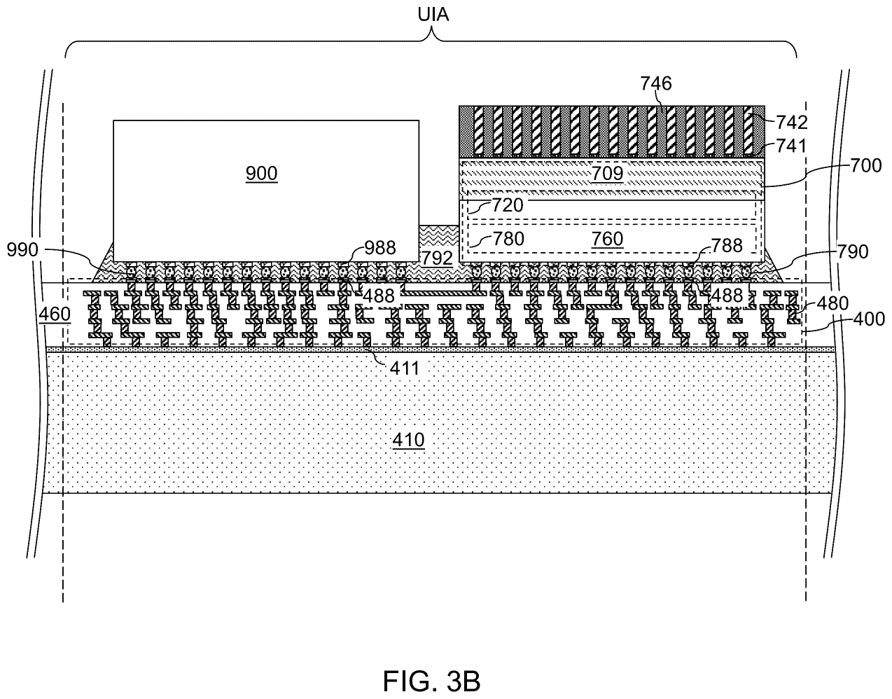

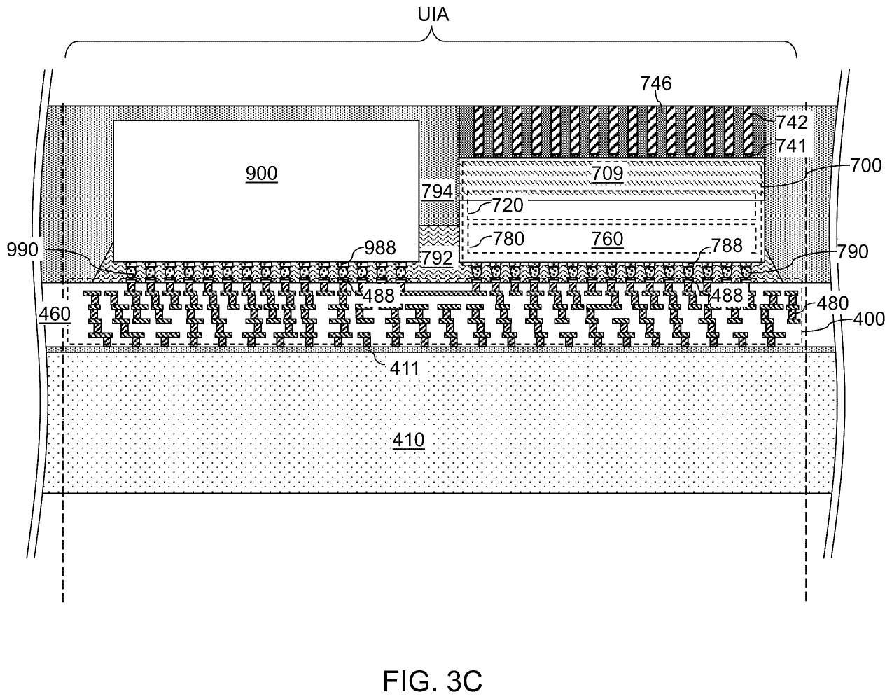

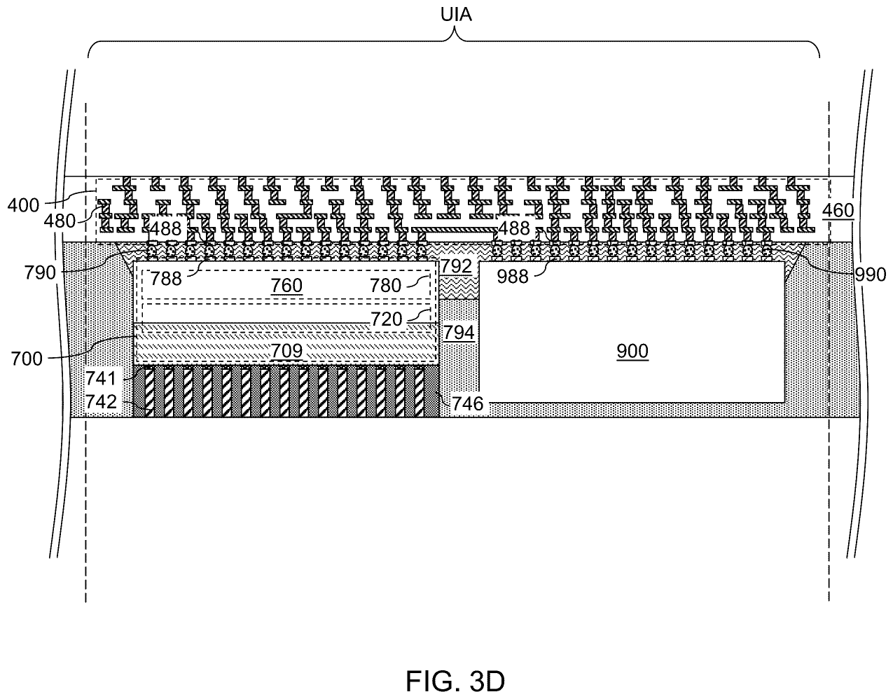

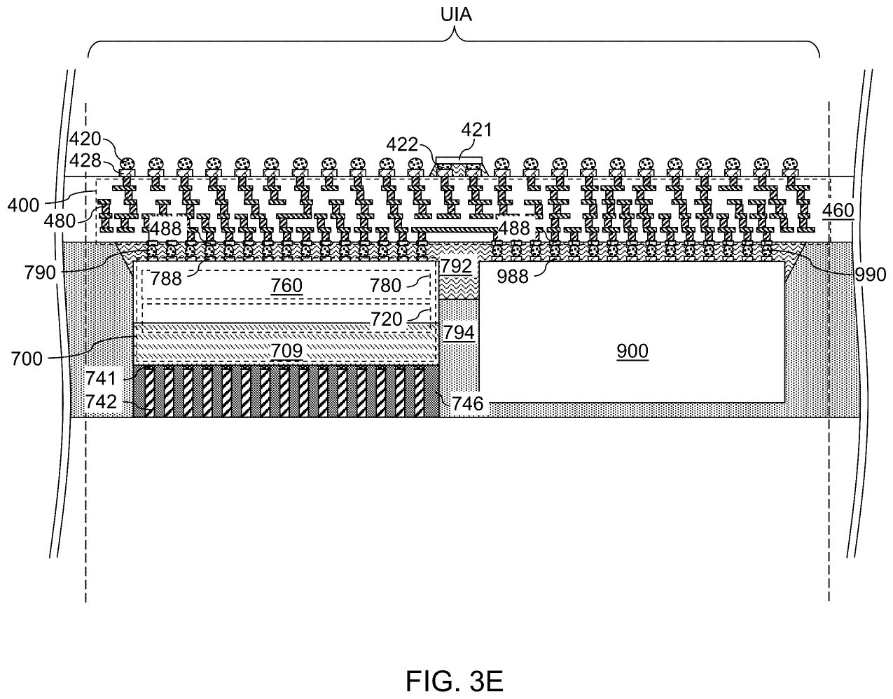

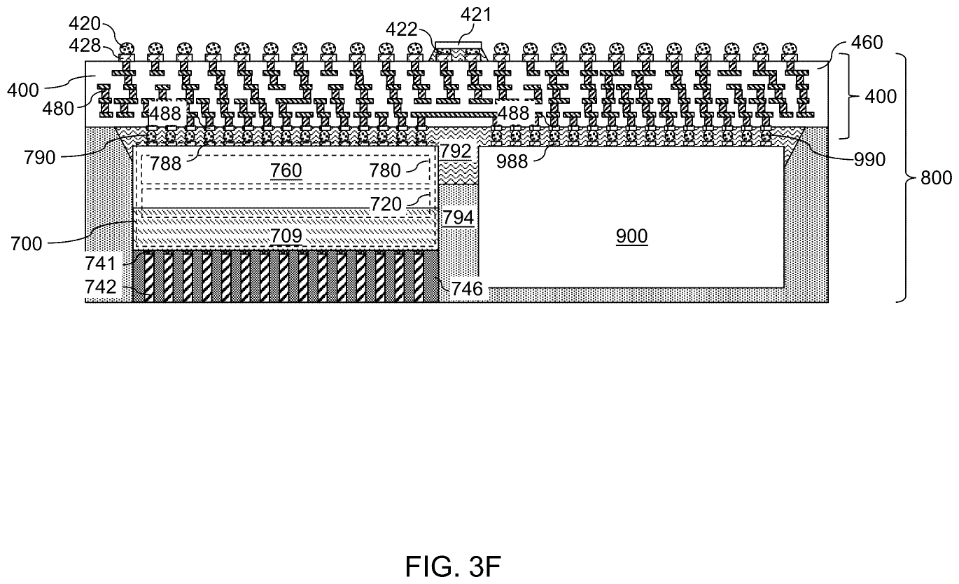

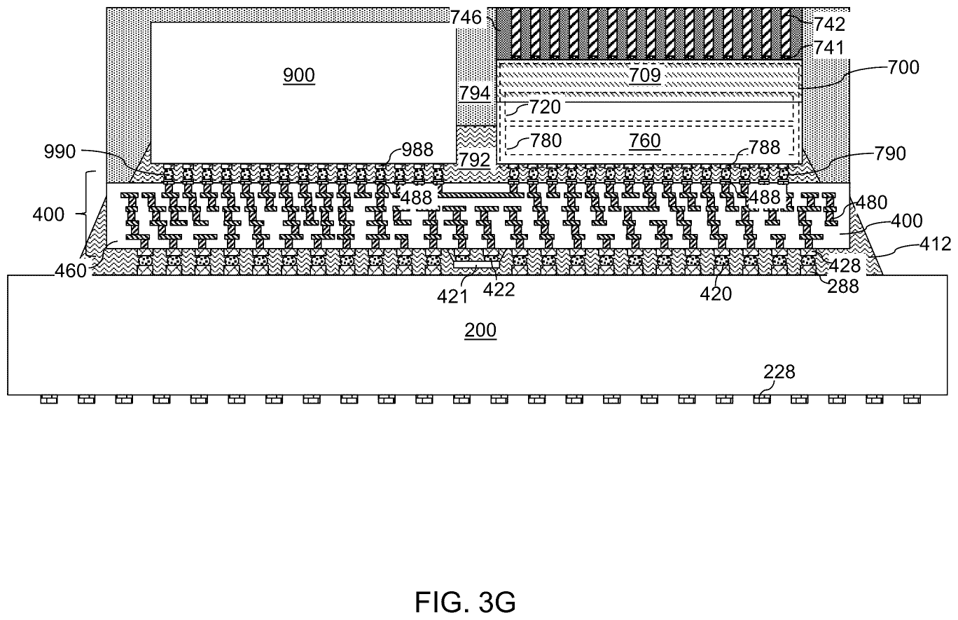

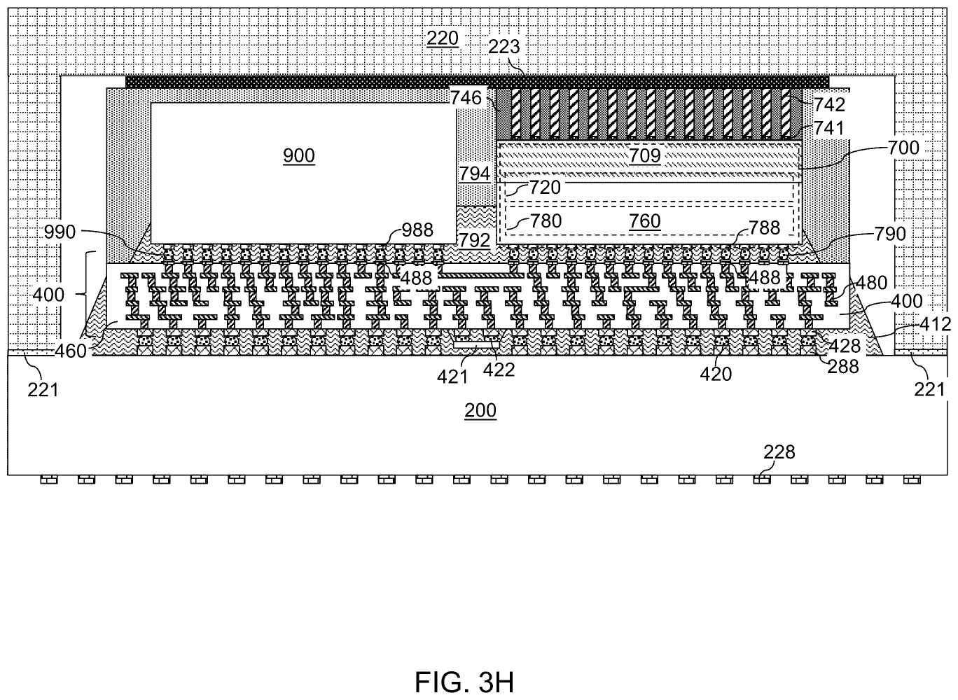

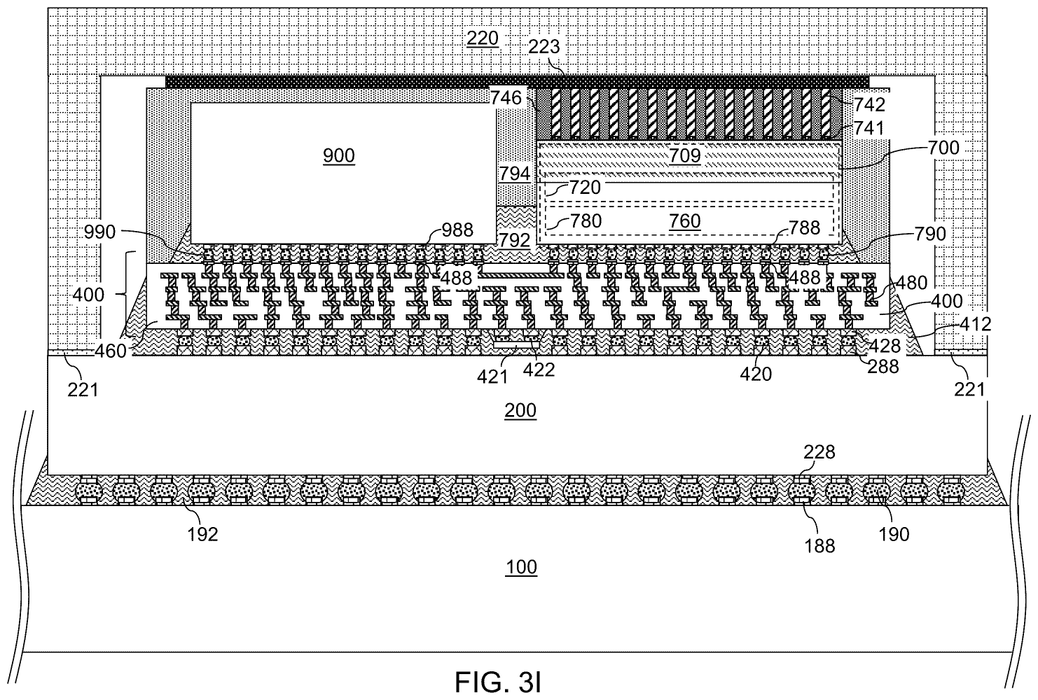

FIG. 3A-3I are sequential vertical cross-sectional views of a first embodiment structure during formation of a bonded assembly including an interposer 400 and a plurality of semiconductor dies (700, 900) according to the first embodiment of the present disclosure.

Referring to FIG. 3A, an assembly of a first semiconductor die 700, an array of metallic seed plates 741, an array of metal pillars 742, and a backside molding compound frame 746 as provided at the processing steps of FIG. 1J and at least one second semiconductor die 900 may be attached to each interposer 400 within the two-dimensional array of interposers 400 that is provided over the handle wafer 410 as illustrated in FIGS. 2A and 2B. The first metal bonding pads 788 of the first semiconductor die 700 may be bonded to the first array of die-side interposer bonding pads 488 through an array of first solder material portions 790 via solder-mediated bondings. Each second semiconductor die 900 comprises respective second metal bonding pads 988 which may be bonded to a respective second array of die-side interposer bonding pads 488 through a respective array of second solder material portions 990 via solder-mediated bondings. For example, microbump bondings may be used to attach the first semiconductor die 700 and the at least one second semiconductor die 900 to each interposer 400.

Generally, the first semiconductor die 700 may be any type of semiconductor die known in the art, and each second semiconductor die 900 may be any type of semiconductor die known in the art. In one embodiment, the first semiconductor die 700 has a first thickness (i.e., a first vertical extent), and each second semiconductor die 900 has a respective second thickness (i.e., a respective second vertical extent) that is greater than the first thickness. For example, the first semiconductor die 700 may comprise a logic die comprising a central processing unit, a graphic processing unit, a neural processing unit, etc., or a system on chip (SoC) die; and the second semiconductor die 900 may comprise a memory die, such as a dynamic random access memory (DRAM) die or a high bandwidth memory (HBM) die. The difference between the thickness of the thickest of the at least one second semiconductor die 900 and the thickness of the first semiconductor die 700 is herein referred to as a die thickness differential. Generally, the die thickness differential may be in a range from 1 micron to 300 microns, such as from 10 microns to 150 microns.

According to an aspect of the present disclosure, the vertical extent (i.e., the thickness) of the combination of an array of metallic seed plates 741, an array of metal pillars 742, and a backside molding compound frame 746 (as provided on the backside of the first semiconductor die 700) is the same as, or is greater than, the die thickness differential. While FIG. 3A illustrates an embodiment in which the vertical extent of the combination of the array of metallic seed plates 741, the array of metal pillars 742, and the backside molding compound frame 746 is greater than the die thickness differential, an embodiment is expressly contemplated herein in which the vertical extent of the combination equals the die thickness differential.

Generally, a second semiconductor die 900 and an assembly (700, 741, 742, 746) comprising a first semiconductor die 700, an array of metallic seed plates 741, an array of metal pillars 742, and a backside molding compound frame 746 may be attached to an interposer 400 such that the most distal surface of the backside molding compound frame 746 is more distal from the interposer 400 than the distal surface of the second semiconductor die 900, or is equidistant from the interposer 400 as the distal surface of the semiconductor die 900. The vertical distance between a horizontal plane including the distal surface of the backside molding compound frame 746 and a horizontal plane including the distal surface of the semiconductor die 900 may be in a range from 0 micron to 200 microns, such as from 0 micron to 100 microns.

Referring to FIG. 3B, an underfill material may be applied around each array of solder material portions (790, 990) to form an underfill material portion, which is herein referred to a as die-interposer underfill material portion 792.

Referring to FIG. 3C, a molding compound material may be applied around the semiconductor dies (700, 900) over the two-dimensional array of interposers 400 (which are interconnect among one another at this processing step). The molding compound material applied at this processing step may comprise any molding compound material that may be used to form backside molding compound frames 746 as described with reference to FIG. 1H. The molding compound material may be cured, and may be subsequently planarized. Excess portions of the applied and cured molding compound material may be removed from above the horizontal plane including the distal surfaces of the backside molding compound frames 746 and the metal pillars 742. A molding compound matrix laterally surrounds each semiconductor die (700, 900) that overlies the two-dimensional array of interposers 400. Each portion of the molding compound matrix that is located within a respective unit interface area UIA laterally surrounds a respective set of multiple semiconductor dies including a first semiconductor die 700 and at least one second semiconductor die 900, and is herein referred to as a multi-die molding compound frame 794. The combination of all material portions overlying the adhesive layer 411 constitutes a reconstituted wafer.

Thus, each multi-die molding compound frame 794 is formed around a second semiconductor die 900 and an assembly (700, 741, 742, 746) of a first semiconductor die 700, an array of metallic seed plates 741, an array of metal pillars 742, and a backside molding compound frame 746. The assembly (700, 741, 742, 746) is attached to the interposer 400 using an array of first solder material portions 790, and the second semiconductor die 900 is attached to the interposer 400 using an array of second solder material portions 990. In one embodiment, a vertical distance between a distal surface of the second semiconductor die 900 and the interposer 400 is less than a vertical distance between distal end surfaces of the metal pillars 742 and the interposer 400, and is greater than a vertical distance between a distal surface of the first semiconductor die 700 and the interposer 400.

Referring to FIG. 3D, the handle wafer 410 is detached from the reconstituted wafer by deactivating the adhesive layer 411. The adhesive layer 411 may be deactivated by a thermal anneal or by irradiation by ultraviolet light. The adhesive layer 411 loses adhesive strength, and the handle wafer 410 may be cleaved from the reconstituted wafer. A suitable surface clean process may be performed to remove residual portions of the adhesive layer 411.

Referring to FIG. 3E, substrate-side interposer bonding pads 428 may be formed on the backside of the interposers 400, i.e., on the side of the interposers 400 that does not face the semiconductor dies (700, 900). The substrate-side interposer bonding pads 428 may be formed as controlled collapse chip connection (C4) bonding pads. Solder material portions for bonding with a packaging substrate may be attached to the substrate-side interposer bonding pads 428. These solder material portions are herein referred to as interposer-substrate solder material portions 420. Optionally, at least one integrated passive device (IPD) 421 may be attached to a subset of the substrate-side interposer bonding pads 428 through additional solder material portions 422 having a lesser height than the interposer-substrate solder material portions 420. An underfill material portion may be formed between each IPD 421 and a respective underlying interposer 400.

Referring to FIG. 3F, the reconstituted wafer may be diced along dicing channels. Each diced portion of the reconstituted wafer comprises a composite package 800. Each composite package comprises an interposer 400; an assembly (700, 741, 742, 746) that is attached to the interposer 400 and comprising a first semiconductor die 700, an array of metal pillars 742 located on a backside of the first semiconductor die 700, and a backside molding compound frame 746 laterally surrounding the array of metal pillars 742; a second semiconductor die 900 that is attached to the interposer 400; and a multi-die molding compound frame 794 laterally surrounding the assembly and the second semiconductor die 900.

Referring to FIG. 3G, a packaging substrate 200 may be bonded to the composite package 800. The packaging substrate 200 may be a cored packaging substrate including a core substrate, or a coreless packaging substrate that does not include a package core. Alternatively, the packaging substrate 200 may include a system-on-integrated packaging substrate (SoIS) including redistribution layers, dielectric interlayers, and/or at least one interposer (such as a silicon interposer). Such a system-integrated packaging substrate may include layer-to-layer interconnections using solder material portions, microbumps, underfill material portions (such as molded underfill material portions), and/or an adhesion film. In some embodiments, the packaging substrate 200 may comprise a system-on-integrated substrate package including a glass epoxy plate with an array of through-plate holes. An array of through-core via structures (not illustrated) including a metallic material may be provided in the through-plate holes. Each through-core via structure may, or may not, include a cylindrical hollow therein. Optionally, dielectric liners (not illustrated) may be used to electrically isolate the through-core via structures from the core substrate.

Substrate-side bonding pads 288 may be provided on one side of the packaging substrate 200, and board-side bonding pads 228 may be provided on another side of the packaging substrate 200. The composite package 800 may be attached to the substrate-side bonding pads 288 of the packaging substrate 200 using the interposer-substrate solder material portions 420. An underfill material may be applied into a gap between the composite package 800 and the packaging substrate 200. The underfill material may comprise any underfill material known in the art.

Referring to FIG. 3H, a thermal interface material (TIM) layer 223 may be applied to the top surface of the composite package 800. In one embodiment, the TIM layer 223 may contact top surfaces of the metal pillars 742. The lateral extent of the TIM layer 223 may be the same as, or may be less than, the lateral extent of the top surface of the multi-die molding compound frame 794. A stiffener structure 220 (which is also referred to as a stabilization ring) may be attached to a peripheral portion of the top surface of the packaging substrate 200, for example, through an adhesive layer 221. The TIM layer 223 may directly contact the top surfaces of the metal pillars 742 and the top surface of the backside molding compound frame 746.

Referring to FIG. 3I, a printed circuit board (PCB) 100 including a PCB substrate and PCB bonding pads 188 may be provided. The PCB 100 includes a printed circuitry (not shown) at least on one side of the PCB substrate. An array of solder joints 190 may be formed to bond the array of board-side bonding pads 228 to the array of PCB bonding pads 188. The solder joints 190 may be formed by disposing an array of solder balls between the array of board-side bonding pads 228 and the array of PCB bonding pads 188, and by reflowing the array of solder balls. An additional underfill material portion, which is herein referred to as a board-substrate underfill material portion 192 or a BS underfill material portion 192, may be formed around the solder joints 190 by applying and shaping an underfill material. The packaging substrate 200 is attached to the PCB 100 through the array of solder joints 190.

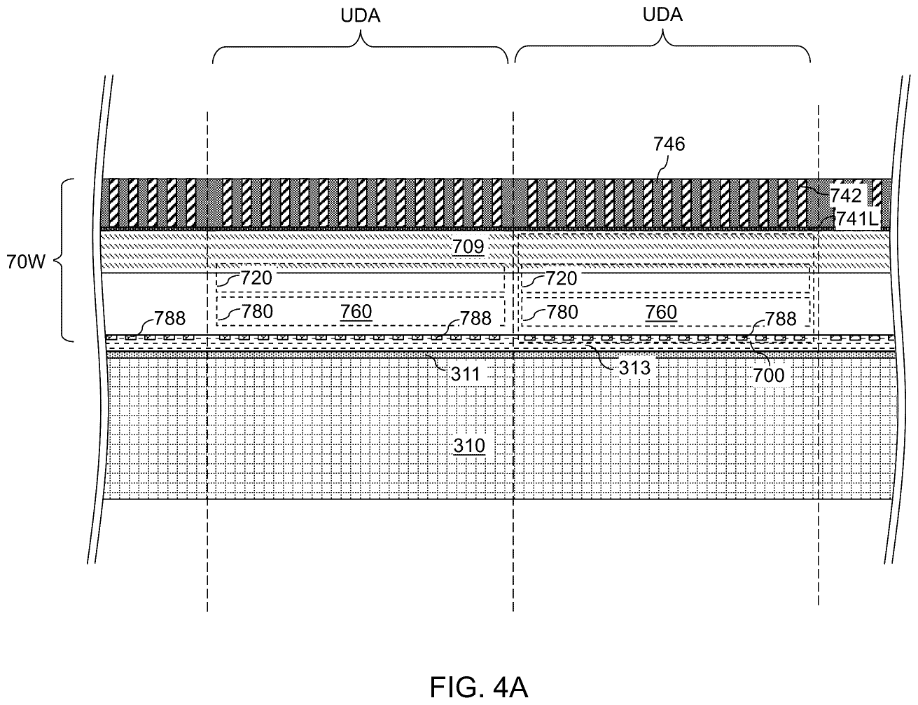

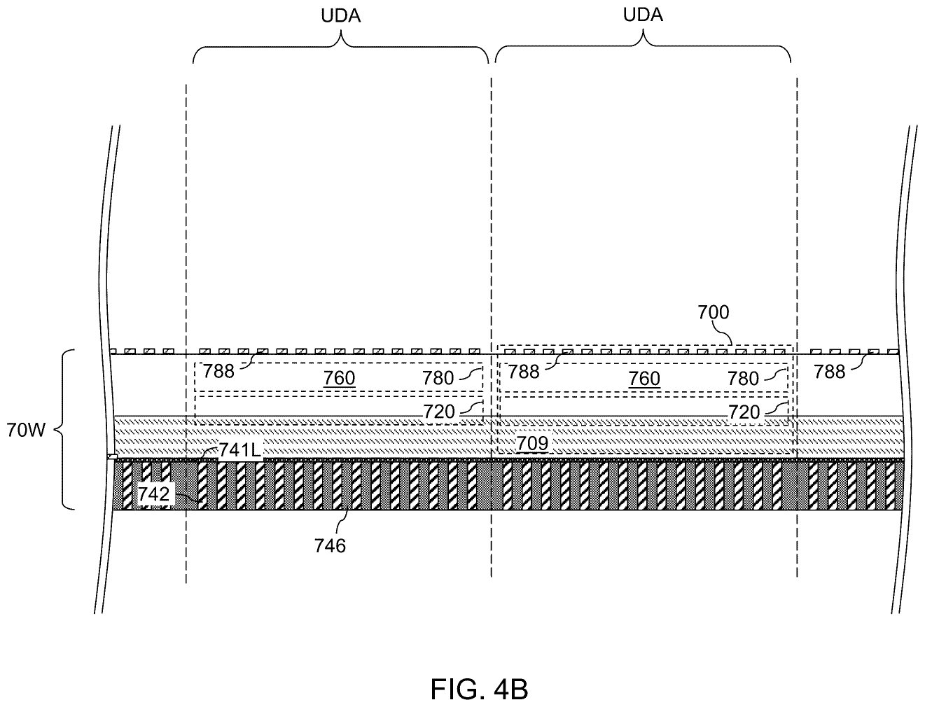

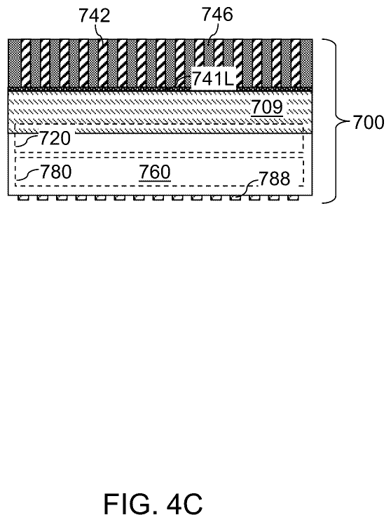

FIG. 4A-4C are sequential vertical cross-sectional views of a second intermediate structure during formation of an assembly comprising a first semiconductor die 700, an array of metal pillars 742, and a backside molding compound frame 746 according to a second embodiment of the present disclosure.

Referring to FIG. 4A, a second intermediate structure may be derived from the first intermediate structure illustrated in FIG. 1F by performing the processing steps described with reference to FIG. 1H without performing the processing steps described with reference to FIG. 1G. In this embodiment, the metallic seed layer 741L is not patterned, and remains as a single contiguous material layer having a uniform thickness on the backside surfaces of the first semiconductor dies 700. In this embodiment, each backside molding compound frame 746 may be formed directly on a physically exposed planar surface of the metallic seed layer 741L, and may be vertically spaced from a respective underlying first semiconductor die 700 by the metallic seed layer 741L.

Referring to FIG. 4B, the processing steps described with reference to FIG. 1I may be performed to detach the carrier wafer 310 from the assembly of the device wafer 70W.

Referring to FIG. 4C, the processing steps described with reference to FIG. 1J may be performed to dice the assembly of the two-dimensional array of first semiconductor dies 700, the metallic seed layer 741L, the arrays of metal pillars 742, and the molding compound matrix (which comprises a two-dimensional array of backside molding compound frames 746) into discrete diced portions. Each discrete diced portion comprises an assembly (700, 741L, 742, 746) of a first semiconductor die 700, a metallic seed layer 741L, an array of metal pillars 742, and a backside molding compound frame 746. Within each assembly (700, 741L, 742, 746), a metallic seed layer 741L contacts a backside surface of the first semiconductor die 700 and contacts each metal pillar 742 within the array of metal pillars 742.

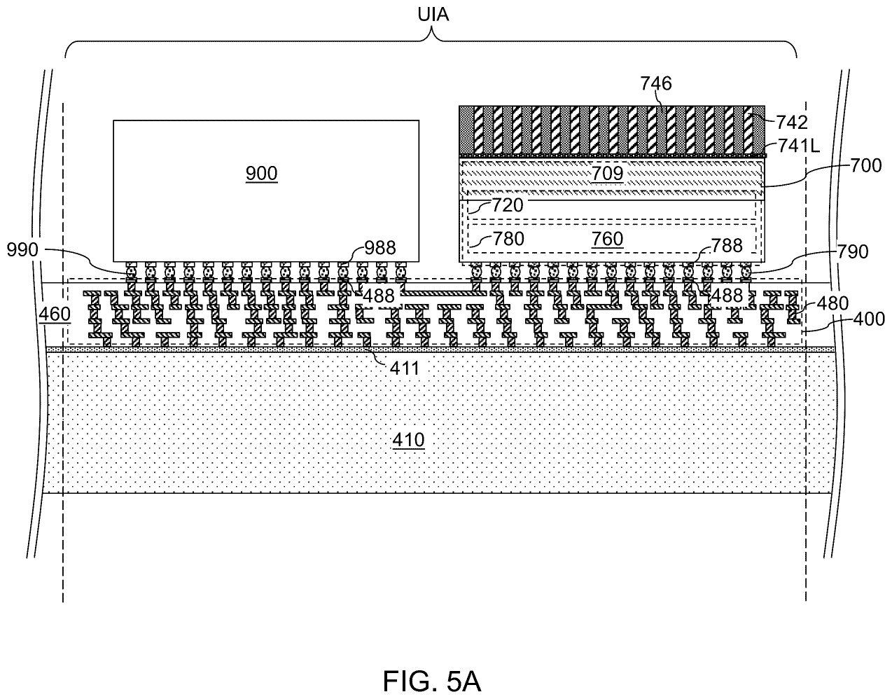

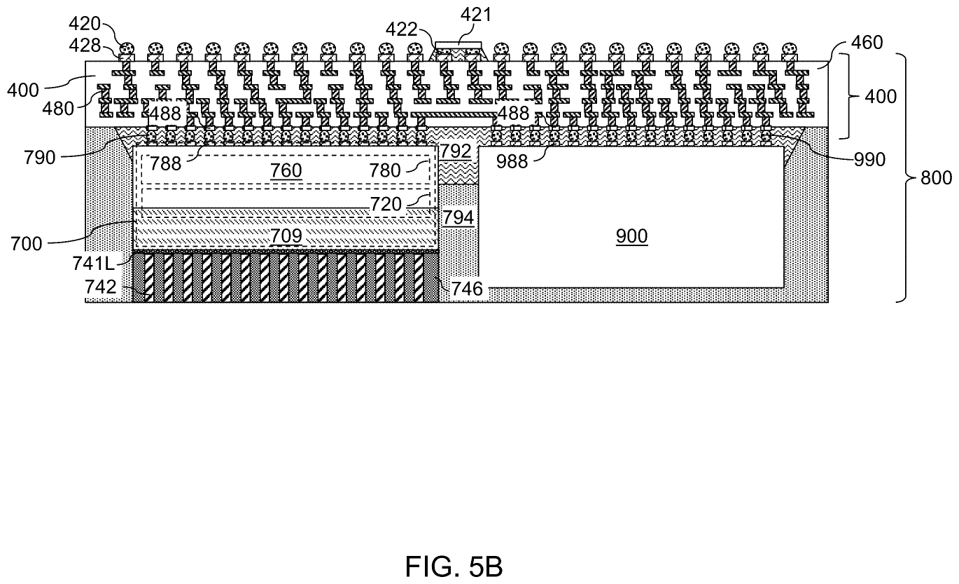

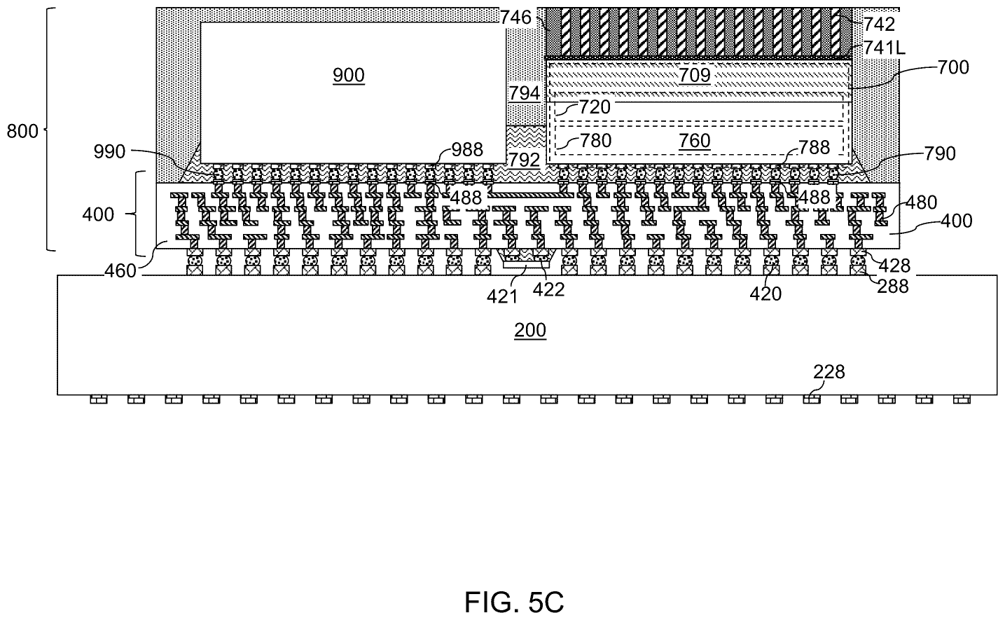

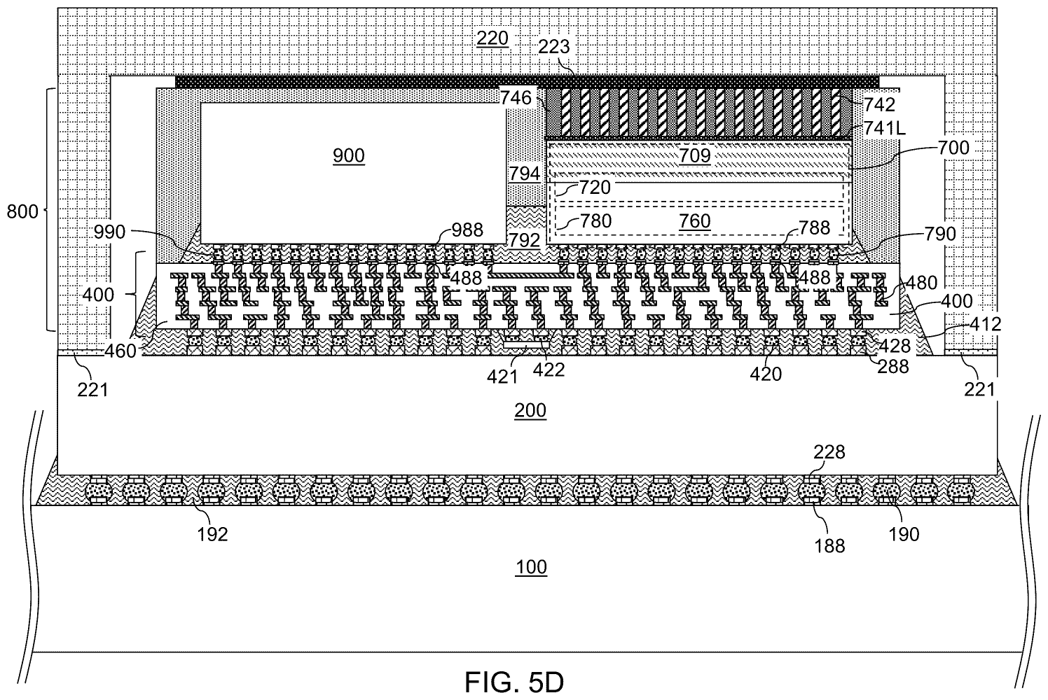

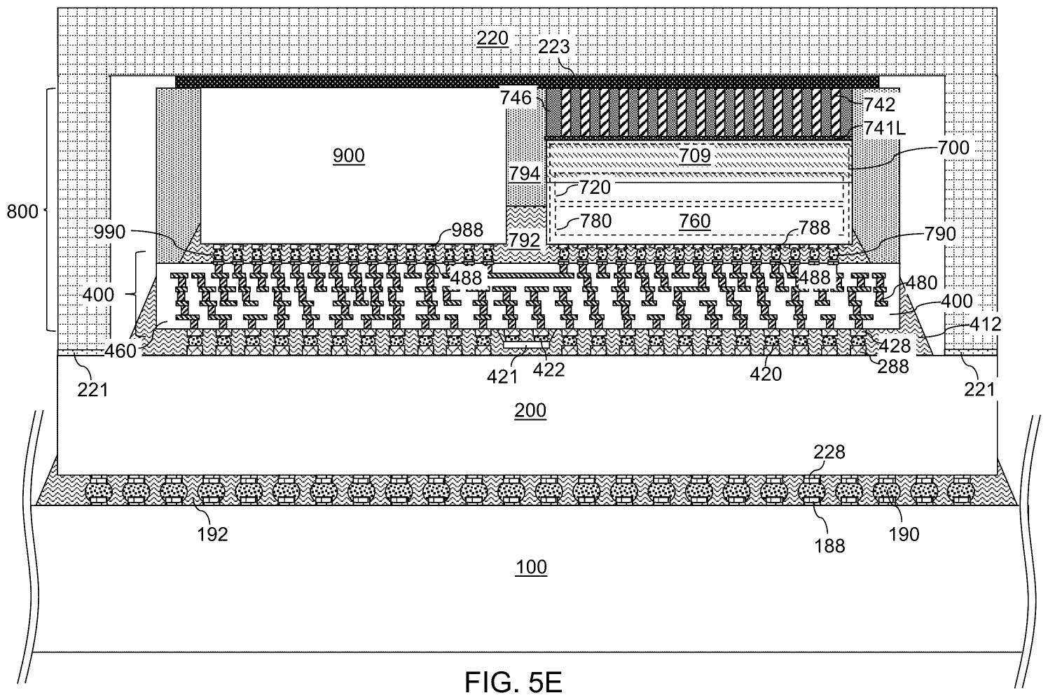

FIG. 5A-5E are sequential vertical cross-sectional views of a second embodiment structure during formation of a bonded assembly including an interposer 400 and a plurality of semiconductor dies (700, 900) according to the second embodiment of the present disclosure.

Referring to FIG. 5A, the processing steps described with reference to FIG. 3A may be performed using assemblies (700, 741L, 742, 746) including a respective set of a first semiconductor die 700, a metallic seed layer 741L, an array of metal pillars 742, and a backside molding compound frame 746 illustrated in FIG. 4C. In this embodiment, the vertical extent (i.e., the thickness) of the combination of a metallic seed layer 741L, an array of metal pillars 742, and a backside molding compound frame 746 (as provided on the backside of the first semiconductor die 700) is the same as, or is greater than, the die thickness differential between the at least one second semiconductor die 900 and the first semiconductor die 700.

In the second embodiment structure, a second semiconductor die 900 and an assembly (700, 741L, 742, 746) comprising a first semiconductor die 700, a metallic seed layer 741L, an array of metal pillars 742, and a backside molding compound frame 746 may be attached to an interposer 400 such that the most distal surface of the backside molding compound frame 746 is more distal from the interposer 400 than the distal surface of the second semiconductor die 900, or is equidistant from the interposer 400 as the distal surface of the semiconductor die 900. The vertical distance between a horizontal plane including the distal surface of the backside molding compound frame 746 and a horizontal plane including the distal surface of the semiconductor die 900 may be in a range from 0 micron to 200 microns, such as from 0 micron to 100 microns.

Referring to FIG. 5B, the processing steps described with reference to FIGS. 3B and 3C may be performed to form a die-interposer underfill material portion 792 and a multi-die molding compound frame 794 within each unit interposer area UIA. The processing steps described with reference to FIG. 3D may be performed to detach the handle wafer 410. The processing steps described with reference to FIG. 3E may be performed to form substrate-side interposer bonding pads 428, and to attach interposer-substrate solder material portions 420 and optionally to attach at least one integrated passive device (IPD) 421. The processing steps described with reference to FIG. 3F may be performed to dice the reconstituted wafer into composite packages 800. Each composite package comprises an interposer 400; an assembly (700, 741L, 742, 746) that is attached to the interposer 400 and comprising a first semiconductor die 700, an array of metal pillars 742 located on a backside of the first semiconductor die 700, and a backside molding compound frame 746 laterally surrounding the array of metal pillars 742; a second semiconductor die 900 that is attached to the interposer 400; and a multi-die molding compound frame 794 laterally surrounding the assembly and the second semiconductor die 900.

Referring to FIG. 5C, the processing steps described with reference to FIG. 3G may be performed to bond a packaging substrate 200 to the composite package 800.

Referring to FIG. 5D, the processing steps described with reference to FIG. 3H may be performed to apply a thermal interface material (TIM) layer 223 to the top surface of the composite package 800, and to attach a stiffener structure 220 to a peripheral portion of the top surface of the packaging substrate 200. The TIM layer 223 may directly contact a top surface of the multi-die molding compound frame 794. In addition, the processing steps described with reference to FIGS. 3B, 3C, and 5B may be performed to form a die-interposer underfill material portion 412.

Referring to FIG. 5E, the processing steps described with reference to FIG. 3I may be performed to attach the packaging substrate 200 to a printed circuit board (PCB) 100. In the second embodiment structure, the backside molding compound frame 746 is vertically spaced from the first semiconductor die 700 by a metallic seed layer 741L having a same lateral extent as the first semiconductor die 700. The TIM layer 223 may directly contact the top surface of the second semiconductor die 900, the top surfaces of the metal pillars 742, and the top surface of the backside molding compound frame 746.

Referring collectively to FIG. 1A-5E, a structure comprising a composite package 800 is provided. The composite package 800 comprises: an interposer 400; an assembly that is attached to the interposer 400 and comprising a first semiconductor die 700, an array of metal pillars 742 located on a backside of the first semiconductor die 700, and a backside molding compound frame 746 laterally surrounding the array of metal pillars 742; a second semiconductor die 900 that is attached to the interposer 400; and a multi-die molding compound frame 794 laterally surrounding the assembly and the second semiconductor die 900.

In one embodiment, the structure further comprises an array of metallic seed plates 741 located between the array of metal pillars 742 and a backside surface of the first semiconductor die 700. In one embodiment, the backside molding compound frame 746 is in direct contact with a backside surface of the first semiconductor die 700. In one embodiment, the structure further comprises a metallic seed layer 741L contacting a backside surface of the first semiconductor die 700 and contacting each metal pillar within the array of metal pillars 742.

In one embodiment, the backside molding compound frame 746 is vertically spaced from the first semiconductor die 700 by a metallic seed layer 741L having a same lateral extent as the first semiconductor die 700. In one embodiment, the assembly is attached to the interposer 400 through an array of first solder material portions 790; and the second semiconductor die 900 is attached to the interposer 400 through an array of second solder material portions 990. In one embodiment, a vertical distance between a distal surface of the second semiconductor die 900 and the interposer 400 is less than a vertical distance between distal end surfaces of the metal pillars 742 and the interposer 400, and is greater than a vertical distance between a distal surface of the first semiconductor die 700 and the interposer 400.

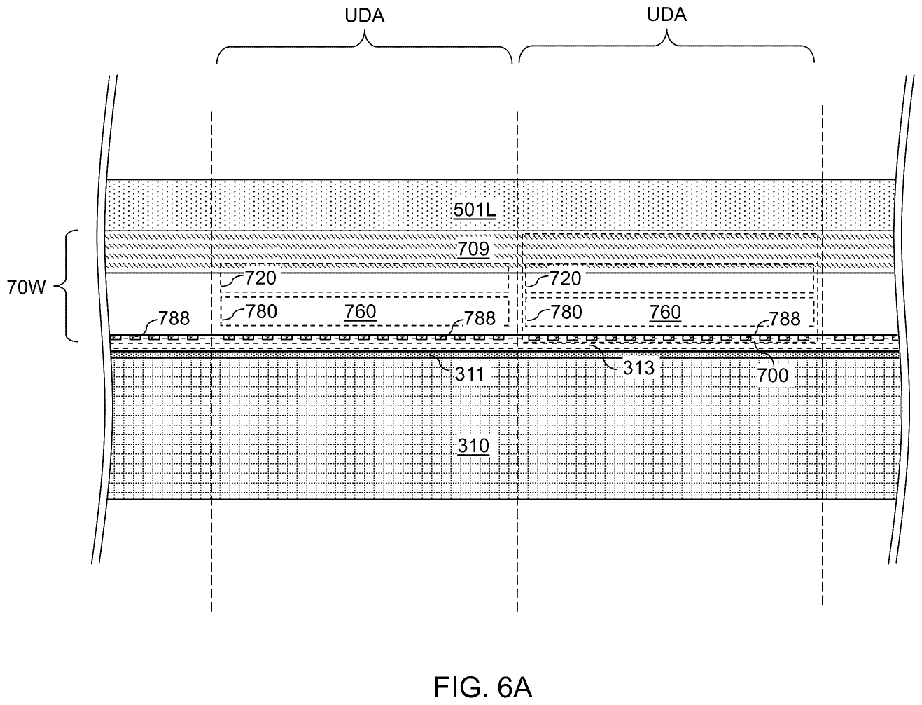

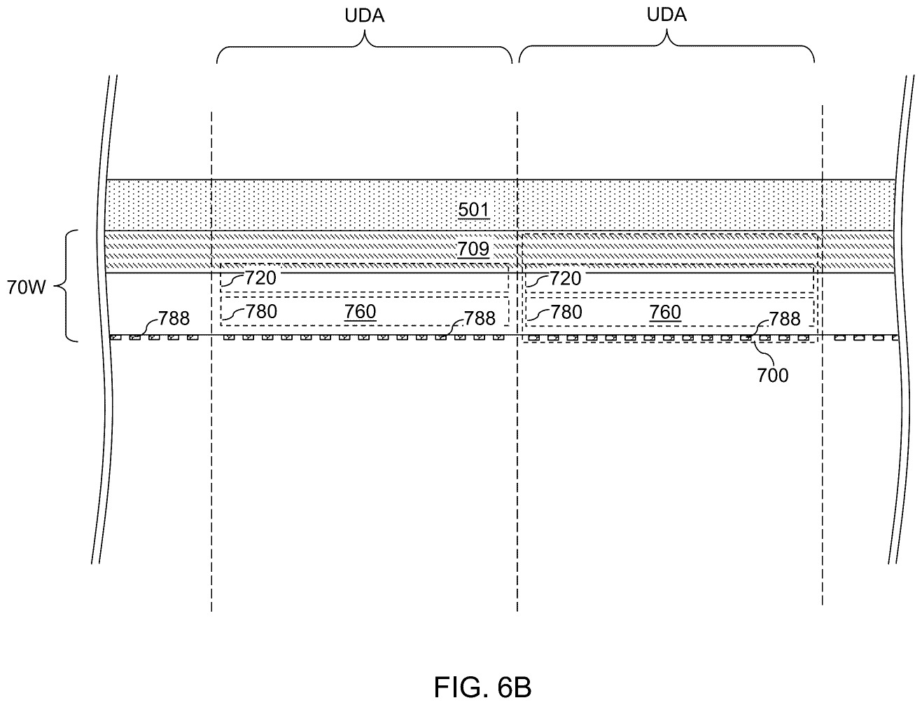

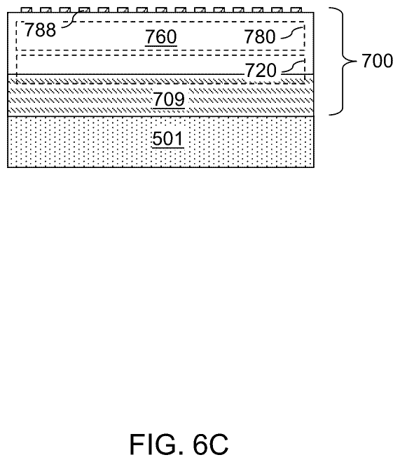

FIG. 6A-6C are sequential vertical cross-sectional views of a third intermediate structure during formation of an assembly comprising a first semiconductor die 700 and a backside die spacer film 501 according to a third embodiment of the present disclosure.

Referring to FIG. 6A, the third intermediate structure may be derived from the first intermediate structure illustrated in FIG. 1C by attaching a die attachment film to the backside of the device wafer 70W. The die attachment film is herein referred to as a backside die spacer film 501L or a continuous backside die spacer film. The backside die spacer film 501L may comprise any material that may be used to provide a desired thickness and mechanical support during subsequent processing steps. In one embodiment, the backside die spacer film 501L may comprise an adhesive film that may be transferred to the backside surface of the device wafer 70W. In one embodiment, the backside die spacer film 501L may comprise a film containing a silver-filled epoxy adhesive, an epoxy resin derived from bisphenol, a novolac epoxy, or a polyimide. The thickness of the backside die spacer film 501L may be in a range from 1 micron to 200 microns, such as from 10 microns to 100 microns, although lesser and greater thicknesses may also be used.

Referring to FIG. 6B, the processing steps described with reference to FIG. 1I may be performed to detach the carrier wafer 310 from the device wafer 70W. The wafer attachment film 311 and the adhesive layer 313 may be removed, and a suitable cleaning process may be performed to remove residual material portions from the wafer attachment film 311 and the adhesive layer 313.

Referring to FIG. 6C, the combination of the device wafer 70W and the backside die spacer film 501L may be diced along dicing channels. Each diced portion of the combination of the device wafer 70W and the backside die spacer film 501L comprises a combination of a first semiconductor die 700 and a backside die spacer film 501. The backside die spacer film 501 is a patterned portion of the backside die spacer film 501L as formed at the processing steps of FIG. 6A. Within each stack of a first semiconductor die 700 and a backside die spacer film 501, sidewalls of the backside die spacer film 501 may be vertically coincident with sidewalls of the first semiconductor die 700. A plurality of stacks of a first semiconductor die 700 and a backside die spacer film 501 may be provided.

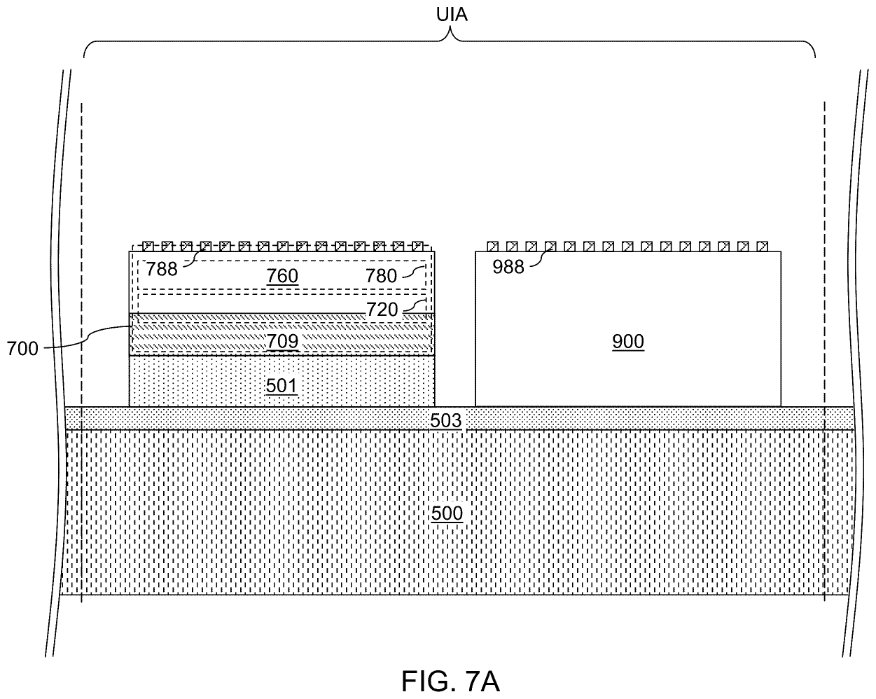

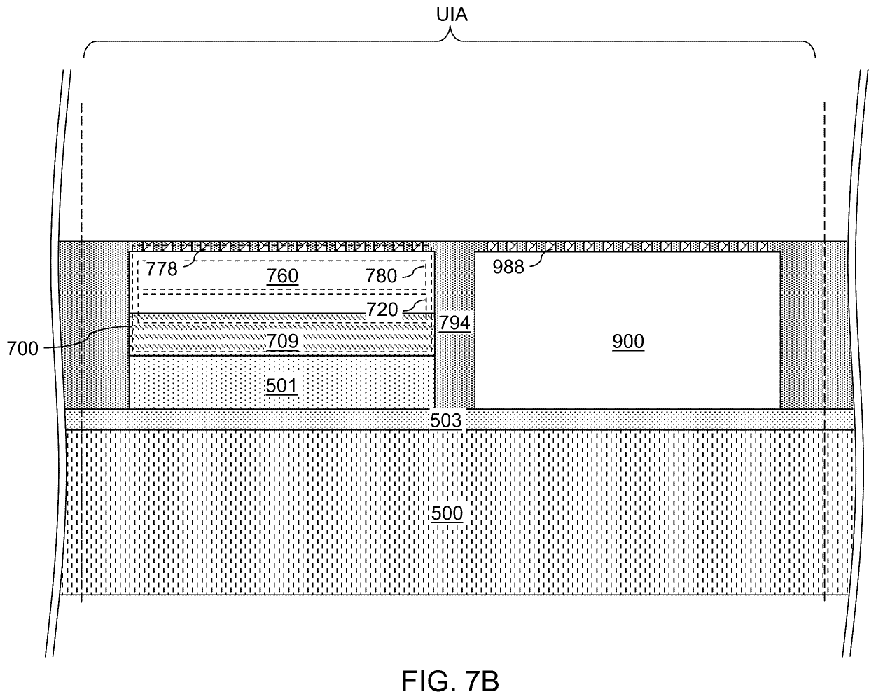

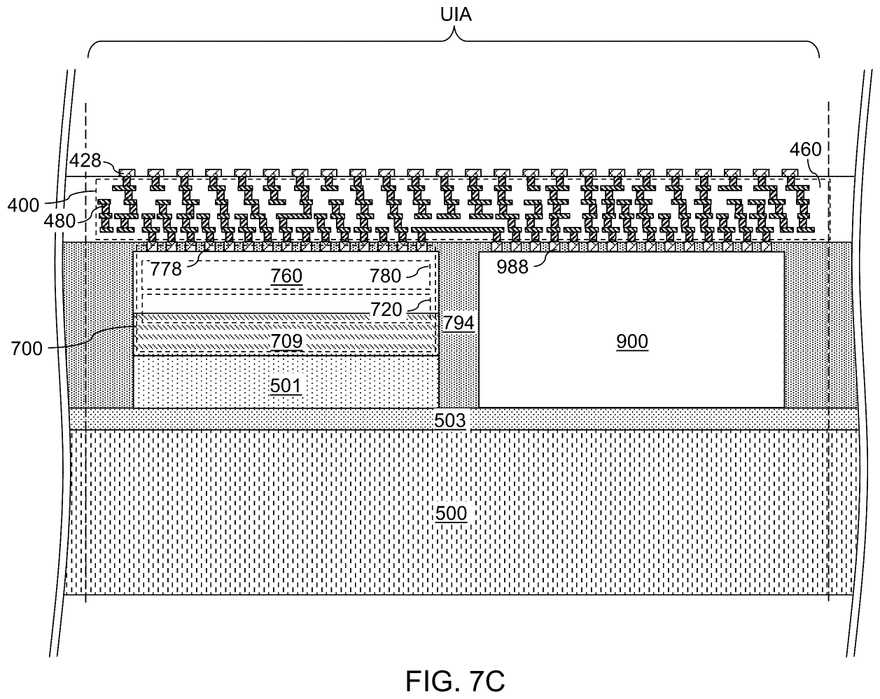

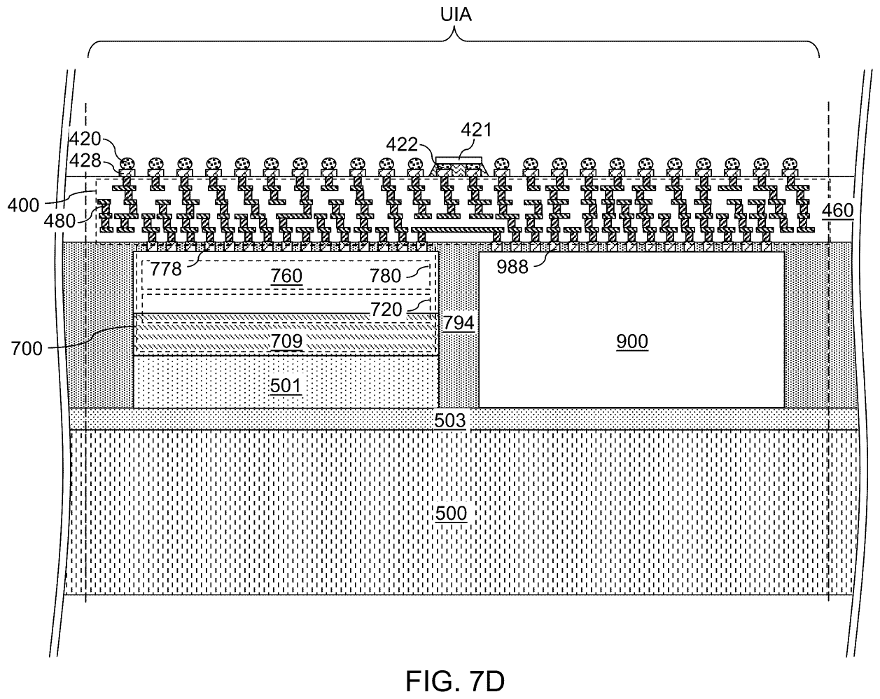

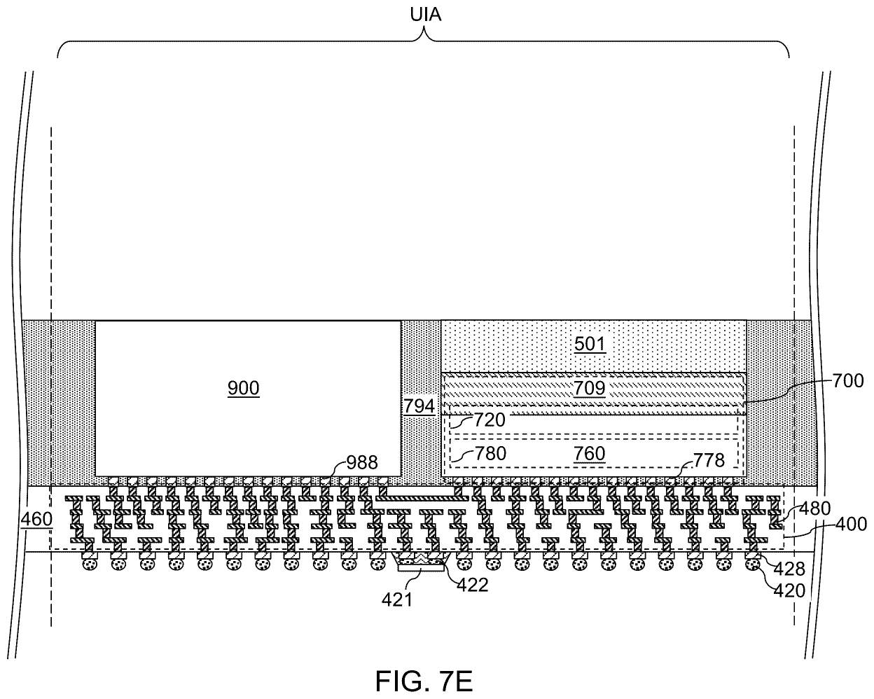

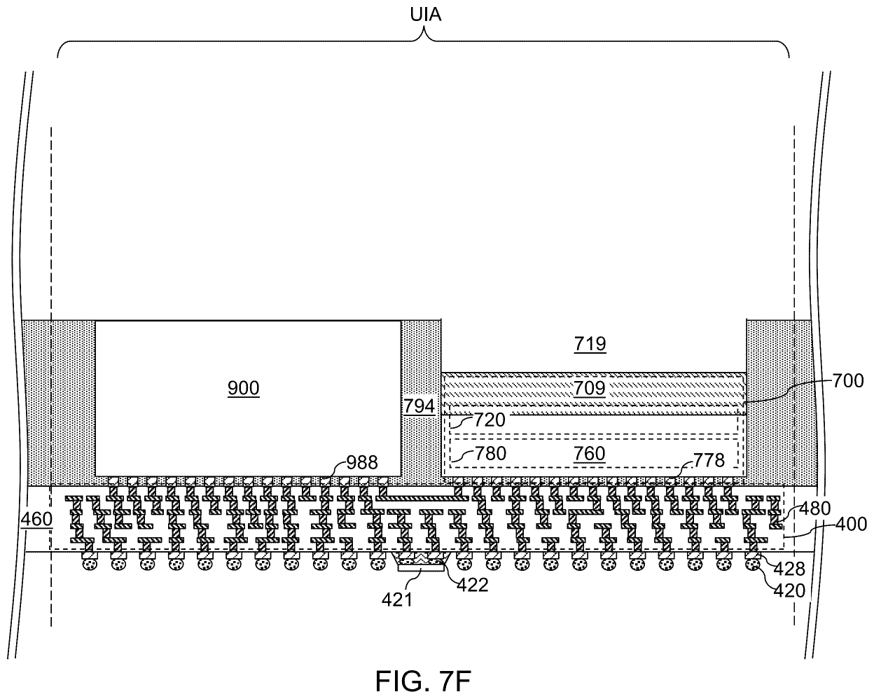

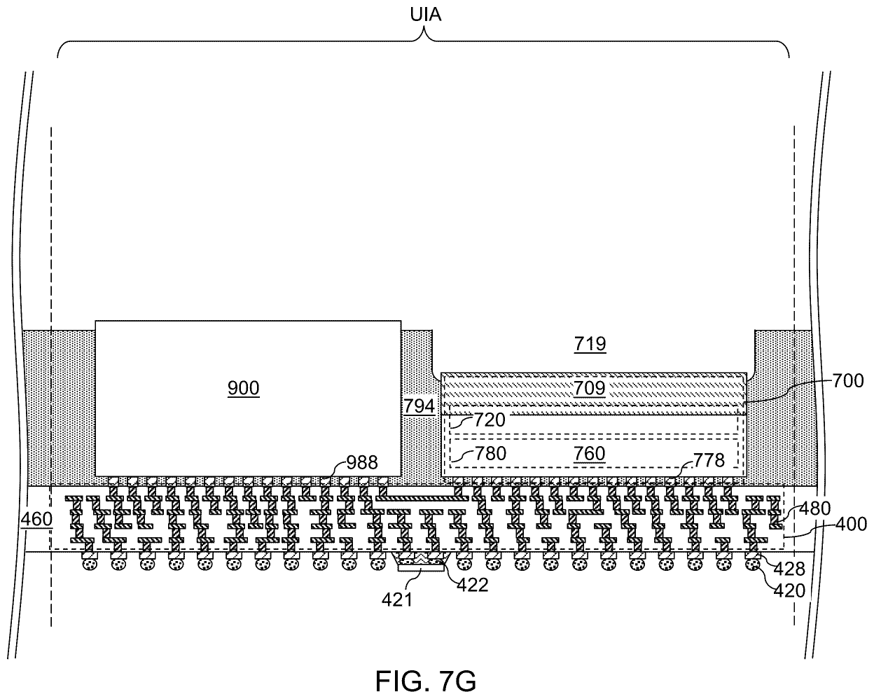

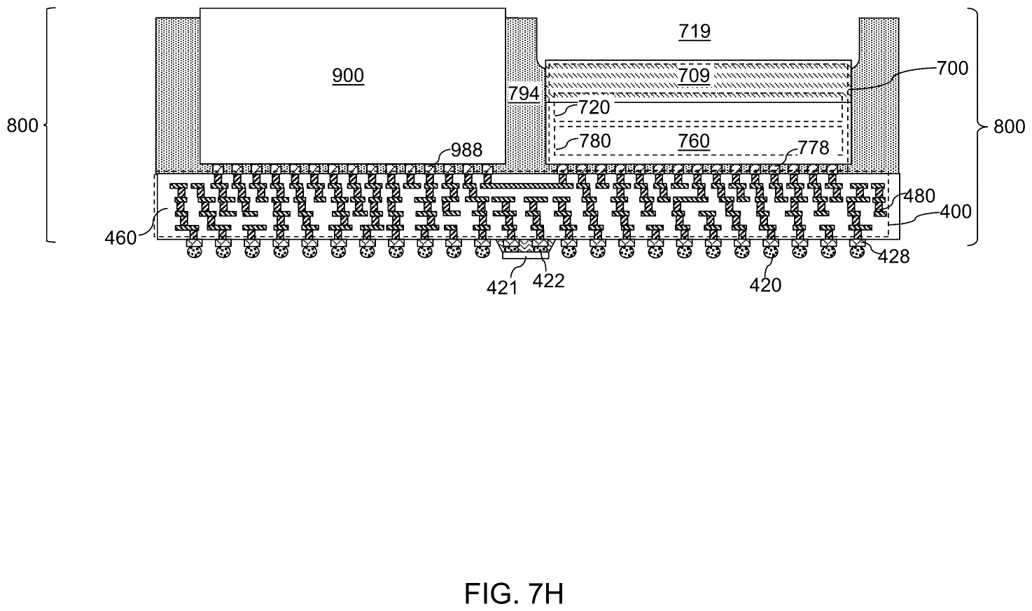

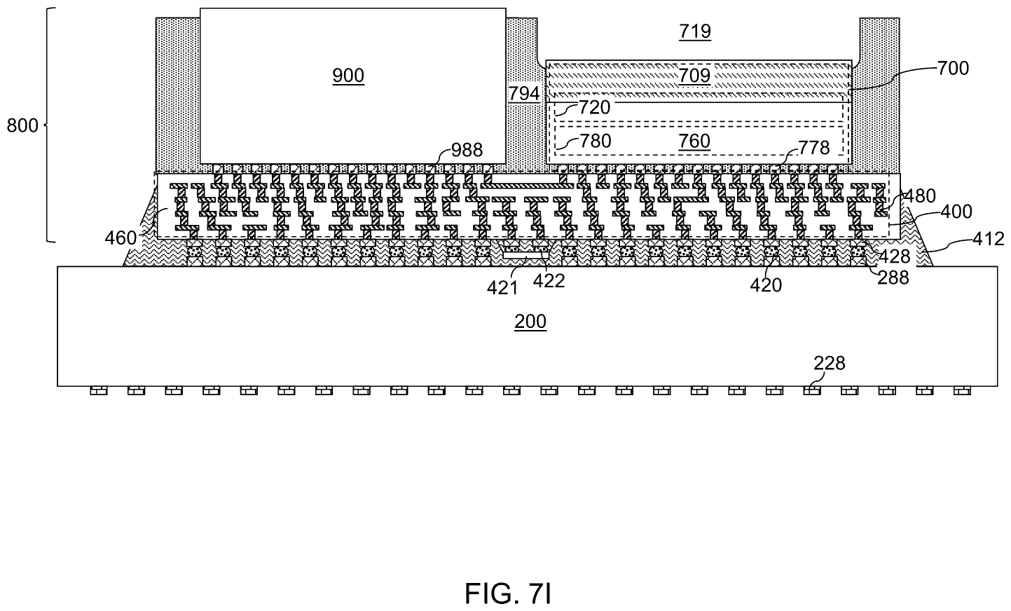

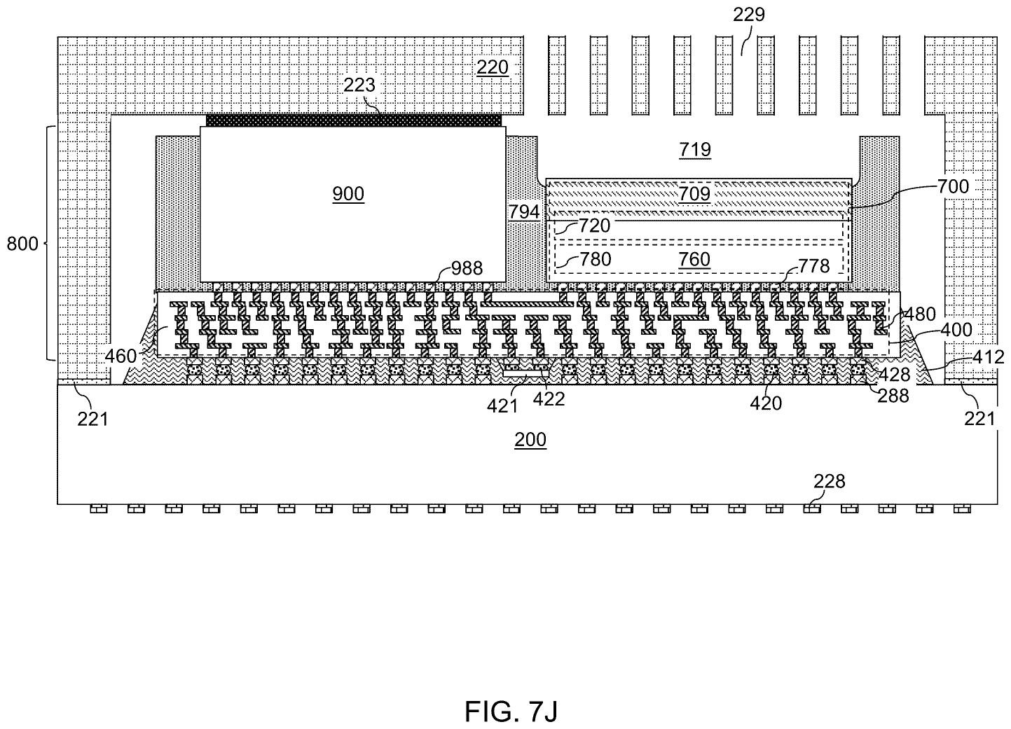

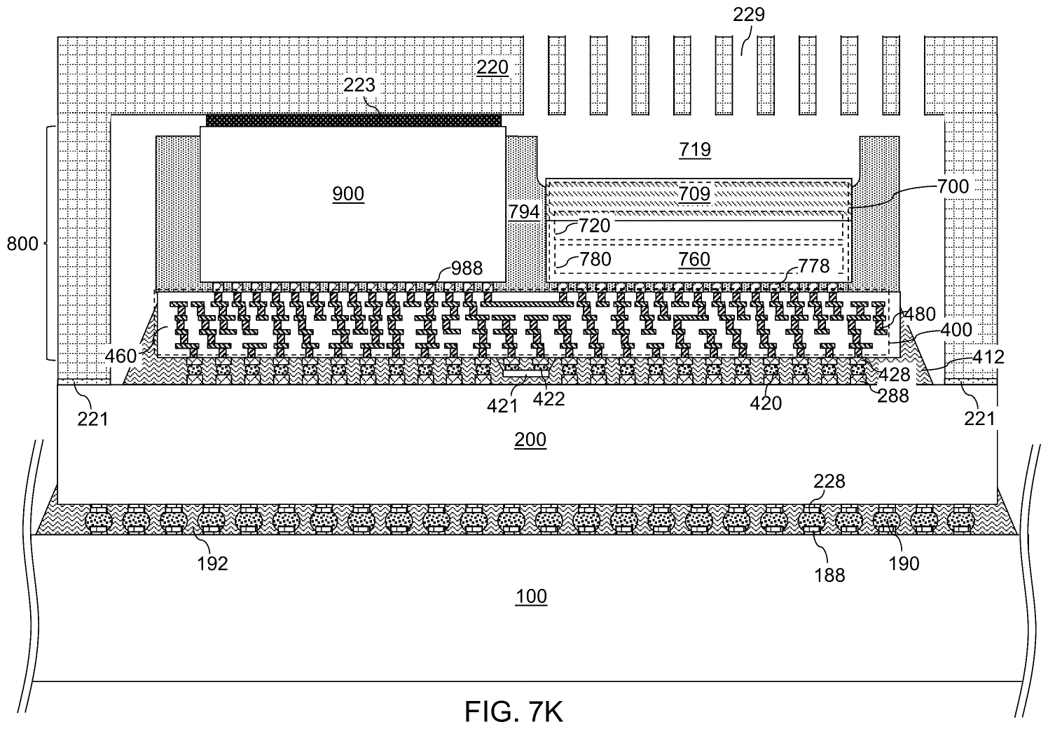

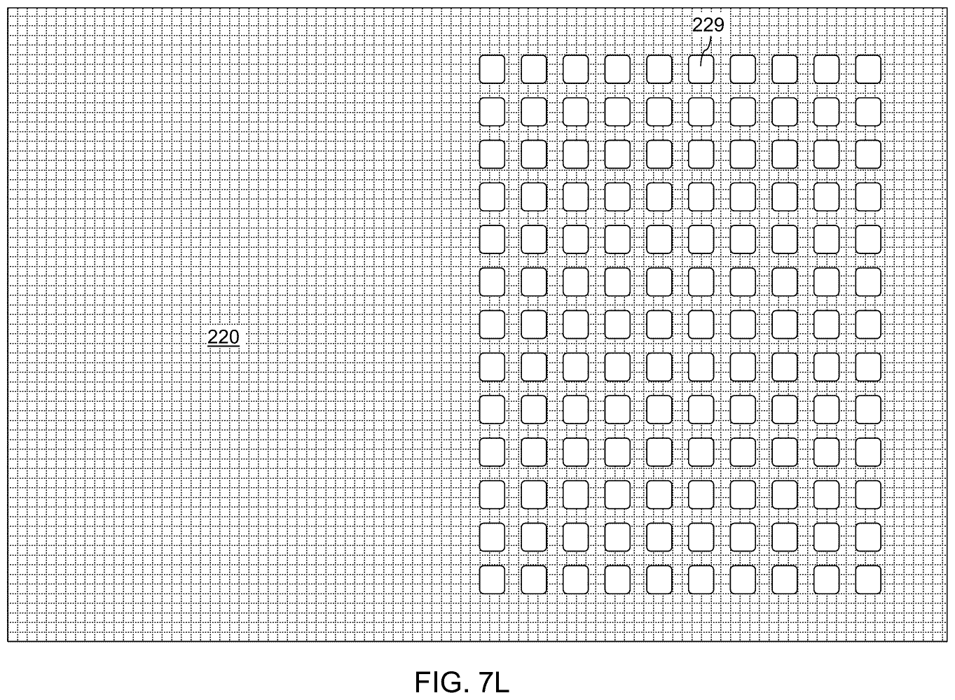

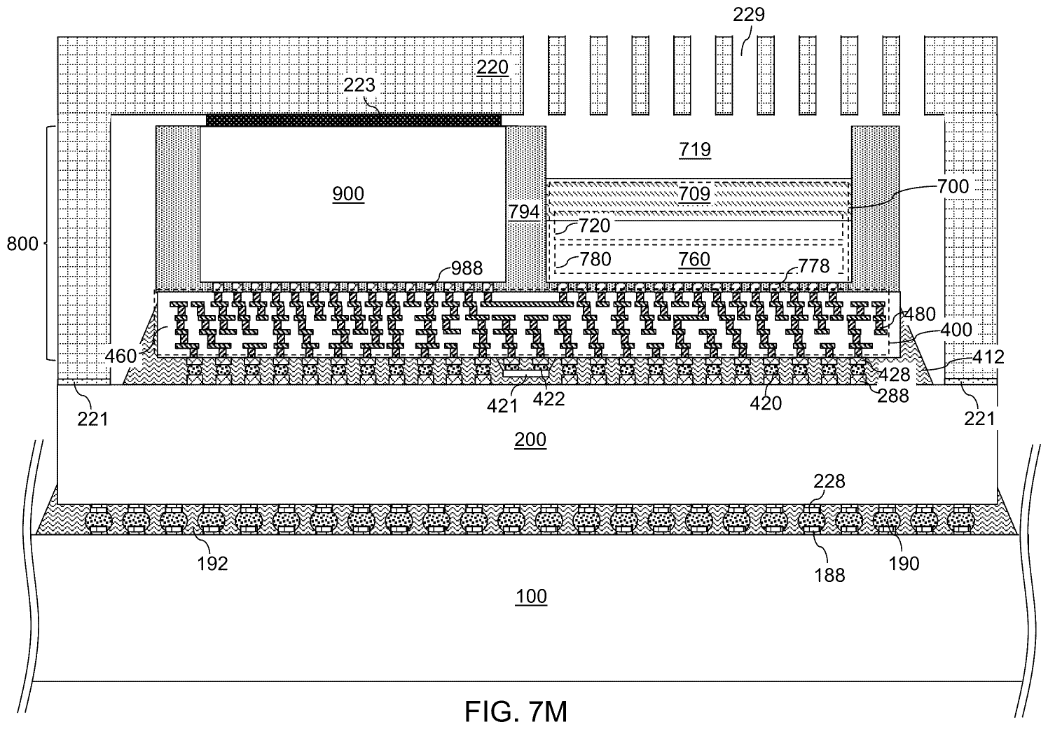

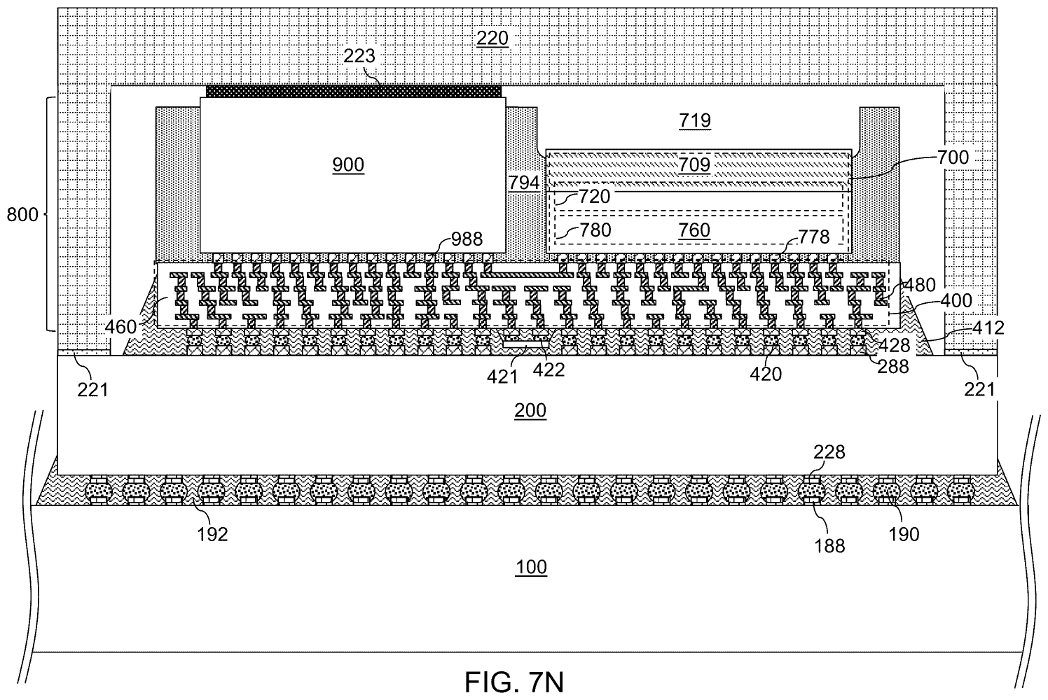

FIG. 7A-7K are sequential vertical cross-sectional views of a third embodiment structure during formation of a bonded assembly including an interposer 400 and a plurality of semiconductor dies (700, 900) according to the fourth embodiment of the present disclosure.

Referring to FIG. 7A, a handle wafer 500 that may provide sufficient mechanical strength may be provided, and a die attachment film 503 may be attached to the front horizontal surface of the handle wafer 500. The die attachment film 503 may comprise any type of die attachment film known in the art, and may have a thickness in a range from 10 microns to 200 microns, although lesser and greater thicknesses may also be used.

The plurality of stacks of a first semiconductor die 700 and a backside die spacer film 501 as provided at the processing steps of FIG. 6C may be attached to the die attachment film 503. Specifically, a stack of a first semiconductor die 700 and a backside die spacer film 501 may be attached to the die attachment film 503 within each unit interposer area UIA, which is the unit area of periodicity for an array of periodic structures that is formed over the handle wafer 500. A two-dimensional periodic array of stacks (700, 501) of a first semiconductor die 700 and a backside die spacer film 501 may be attached to the die attachment film 503. In addition, at least one two-dimensional array of additional semiconductor dies may be attached to the die attachment film 503. For example, a two-dimensional array of second semiconductor dies 900 may be attached to the die attachment film 503 such that each second semiconductor die 900 is attached to the die attachment film 503 within a respective unit interposer area UIA.

As discussed above, the first semiconductor die 700 within each unit interposer area UIA may be any type of semiconductor die, and the second semiconductor die 900 within each unit interposer area UIA may be any type of semiconductor die. According to an aspect of the present disclosure, the first semiconductor die 700 may have a first thickness, and the second semiconductor die 900 may have a second thickness that is greater than the first thickness. In one embodiment, the thickness of the backside die spacer film 501 may be the same as the difference between the second thickness and the first thickness. In one embodiment, the thickness of the backside die spacer film 501 may be in a range from 1 micron to 200 microns, such as from 10 microns to 100 microns, although lesser and greater thicknesses may also be used. The topmost surfaces of the first semiconductor dies 700 may be coplanar with the topmost surfaces of the second semiconductor dies 900. In one embodiment, the top surfaces of the first metal bonding pads 788 of the first semiconductor dies 700 may be located within the same horizontal plane as the topmost surfaces of the second metal bonding pads 988.

Referring to FIG. 7B, a molding compound material may be applied around the semiconductor dies (700, 900) over the die attachment film 503. Specifically, a molding compound material may be applied around the stacks (700, 501) of a respective first semiconductor die 700 and a respective backside die spacer film 501 and around the second semiconductor dies 900. The molding compound material applied at this processing step may comprise any molding compound material that may be used to form backside molding compound frames 746 as described with reference to FIG. 1H.

The molding compound material may be cured, and may be subsequently planarized. Excess portions of the applied and cured molding compound material may be removed from above the horizontal plane including the topmost surfaces of the first semiconductor dies 700 and the second semiconductor dies 900 by performing a planarization process such as a chemical mechanical polishing process. The top surfaces of the first metal bonding pads 788 of the first semiconductor dies 700 and the top surfaces of the second metal bonding pads 988 of the second semiconductor dies 900 may be physically exposed after the planarization process.

The remaining portion of the molding compound material constitutes a molding compound matrix, which laterally surrounds each semiconductor die (700, 900) that overlies the handle wafer 500. Each portion of the molding compound matrix that is located within a respective unit interface area UIA laterally surrounds a respective set of multiple semiconductor dies including a first semiconductor die 700 and at least one second semiconductor die 900, and is herein referred to as a multi-die molding compound frame 794. The combination of all material portions overlying the die attachment film 503 constitutes a reconstituted wafer.

Each multi-die molding compound frame 794 is formed around a second semiconductor die 900 and a stack (700, 501) of a first semiconductor die 700 and a backside die spacer film 501. The stack (700, 501) is attached to the handle wafer 500 through the die attachment film 503. In one embodiment, a vertical distance between a distal surface of the second semiconductor die 900 and the handle wafer 500 is the same as a vertical distance between a distal surface of the first semiconductor die 700 and the handle wafer 500.

Referring to FIG. 7C, a two-dimensional array of interposers 400 may be formed over the combination of the two-dimensional array of first semiconductor dies 700, the at least one two-dimensional array of second semiconductor dies 900, and the molding compound matrix (which includes a two-dimensional array of multi-die molding compound frames 794). The two-dimensional array of interposers 400 is incorporated into the reconstituted wafer.

The two-dimensional array of interposers 400 may be formed, for example, by forming redistribution dielectric layers 460, redistribution wiring interconnects 480, and substrate-side interposer bonding pads 428. Generally, the redistribution dielectric layers 460 and the redistribution wiring interconnects 480 may be formed by performing the processing steps described with reference to FIGS. 2A and 2B. The substrate-side interposer bonding pads 428 may be formed, for example, by performing the processing steps described with reference to FIG. 3E.

Referring to FIG. 7D, the processing steps described with reference to FIG. 3E may be performed to form interposer-substrate solder material portions 420 on the substrate-side interposer bonding pads 428. Optionally, at least one integrated passive device (IPD) 421 may be attached to a subset of the substrate-side interposer bonding pads 428 through additional solder material portions 422 having a lesser height than the interposer-substrate solder material portions 420. An underfill material portion may be formed between each IPD 421 and a respective underlying interposer 400.

Referring to FIG. 7E, the die attachment film 503 may be deactivated, and the handle wafer 500 may be detached from the reconstituted wafer. The die attachment film 503 may be deactivated by a thermal anneal, or may be deactivated by ultraviolet radiation through the handle wafer 500 (if the die attachment film 503 comprises an ultraviolet decomposable material and in instances in which the handle wafer 500 comprises a transparent material).

Referring to FIG. 7F, the backside die spacer films 501 may be removed, for example, by peeling each of the backside die spacer films 501 from a respective underlying first semiconductor die 700. For example, localized vacuum suctions may be used to peel the backside die spacer films 501 from the underlying first semiconductor dies 700. A recess cavity 719 that is laterally bounded by a respective multi-die molding compound frame 794 may be formed within each unit interposer area UIA in a volume from which a backside die spacer film 501 is removed. Within each unit interposer area UIA, the distal surface of the second semiconductor die 900 is more distal from the interposer 400 than the distal surface of the first semiconductor die 700 is from the interposer 400.

Referring to FIG. 7G, a surface clean process, an isotropic recess etch process, and/or an anisotropic recess etch process may be optionally performed to isotropically or anisotropically recess physically exposed surfaces of the multi-die molding compound frames 794. The surface clean process, the isotropic recess etch process, and/or the anisotropic recess etch process may remove the material of the multi-die molding compound frames 794 at a controlled removal rate. The top surface of each multi-die molding compound frame 794 may be vertically recessed relative to the horizontal plane including the top surfaces of the second semiconductor dies 900. The vertical recess distance of the top surface of each multi-die molding compound frame 794 relative to the horizontal plane including the top surfaces of the second semiconductor dies 900 may be in a range from 100 nm to 10 microns, such as from 1 micron to 5 microns, although lesser and greater vertical recess distances may also be used. In one embodiment, upper surface segments of each sidewall of the first semiconductor dies 700 may be physically exposed to the recess cavity 719, which is expanded by the surface clean process, the isotropic recess etch process, and/or the anisotropic recess etch process.

Referring to FIG. 7H, the reconstituted wafer described with reference to FIG. 7G may be diced along dicing channels. Each diced portion of the reconstituted wafer constitutes a composite package 800. The composite package 800 comprises: an interposer 400; a first semiconductor die 700 that is attached to a first side of the interposer 400; and a second semiconductor die 900 that is attached the first side of the interposer 400 and laterally spaced from the first semiconductor die 700. A distal surface of the first semiconductor die 700 is more proximal to the interposer 400 than a distal surface of the second semiconductor die 900 is to the interposer 400.

In one embodiment, the distal surface of the first semiconductor die 700 is physically exposed to a gas-phase ambient (such as air at atmospheric pressure). In one embodiment, the composite package 800 further comprises a multi-die molding compound die frame 794 that laterally surrounds the first semiconductor die 700 and the second semiconductor die 900; and the distal surface of the second semiconductor die 900 is physically exposed to a recess cavity 719 that is laterally surrounded by the multi-die molding compound die frame 794.

In one embodiment, a distal horizonal surface of the molding compound die frame 794 is more proximal to the interposer 400 than the distal surface of the second semiconductor die 900 is to the interposer 400. In one embodiment, the recess cavity 719 comprises a peripheral downward-protruding portion to which sidewalls of the first semiconductor die 700 are physically exposed. In one embodiment, a distal surface of the molding compound die frame 794 is coplanar with the distal surface of the second semiconductor die 900.

Referring to FIG. 7I, the processing steps described with reference to FIG. 3G may be performed to bond a packaging substrate 200 to the composite package 800.

Referring to FIG. 7J, the processing steps described with reference to FIG. 3H may be performed to apply a thermal interface material (TIM) layer 223 to the top surface of the composite package 800, and to attach a stiffener structure 220 to a peripheral portion of the top surface of the packaging substrate 200. The TIM layer 223 may directly contact a top surface of the second semiconductor die 900. According to an aspect of the present disclosure, the stiffener structure 220 may have at least one opening 229 (such as a two-dimensional array of cylindrical openings) that overlies the first semiconductor die 700. The total number of the at least one opening 229 may be, for example, in a range from 1 to 1,000,000.

Referring to FIGS. 7K and 7L, the processing steps described with reference to FIG. 3I may be performed to attach the packaging substrate 200 to a printed circuit board (PCB) 100. In the second embodiment structure, the backside molding compound frame 746 is vertically spaced from the first semiconductor die 700 by a metallic seed layer 741L having a same lateral extent as the first semiconductor die 700.

Referring to FIG. 7M, a first alternative configuration of the third embodiment structure according to the third embodiment of the present disclosure is illustrated. In this configuration, the processing steps described with reference to FIG. 7G may be omitted, and/or a surface clean process may be performed with a cleaning chemistry that does not collaterally remove the material of the molding compound die frame 794. In this embodiment, the top surface of the molding compound die frame 794 may be coplanar with the top surface of the second semiconductor die 900.

Referring to FIG. 7N, a second alternative configuration of the third embodiment structure according to the third embodiment of the present disclosure is illustrated. The second alternative configuration of the third embodiment structure may be derived from the structures illustrated in FIGS. 7K, 7L, and/or 7M by employing a stiffener structure 220 that does not contain any opening 229 in a cap portion thereof. The top surface of the molding compound die frame 794 may be recessed relative to, or may be coplanar with, the top surface of the second semiconductor die 900.

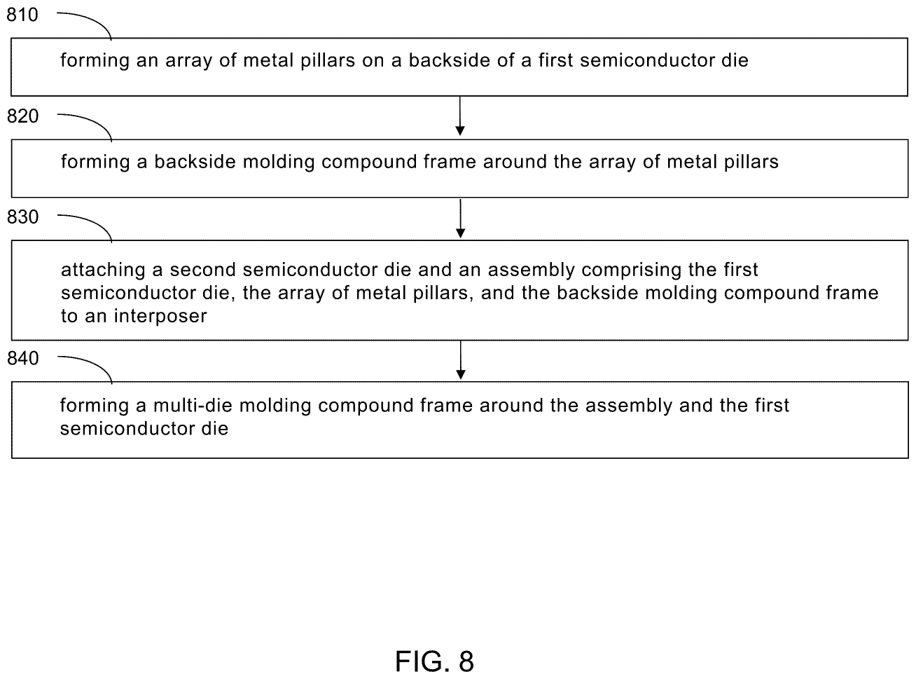

FIG. 8 is a first flowchart illustrating steps for forming a device structure according to an embodiment of the present disclosure.

Referring to step 810 and FIG. 1A-1E and 4A, an array of metal pillars 742 may be formed on a backside of a first semiconductor die 700.

Referring to step 820 and FIG. 1F-1H and 4A, a backside molding compound frame 746 may be formed around the array of metal pillars 742.

Referring to step 830 and FIGS. 1I, 1J, 2A and 2B, 3A, 4B, 4C, and 5A, a second semiconductor die 900 and an assembly {(700, 741, 742, 746) or (700, 741L, 742, 746)} comprising the first semiconductor die 700, the array of metal pillars 742, and the backside molding compound frame 746 may be attached to an interposer 400.

In one embodiment, the method may further include the steps of forming a metallic seed layer 741 directly on a backside horizontal surface of the first semiconductor die 700; forming a plating matrix layer 747 including an array of pillar-shaped cavities 749 over the metallic seed layer 741; and forming the array of metal pillars 742 in the array of pillar-shaped cavities 749. In one embodiment, the method may also include removing the plating matrix layer 747 selectively to the array of metal pillars 742 and the metallic seed layer 741, wherein the backside molding compound frame is formed directly on the array of metal pillars 742 after removal of the plating matrix layer 747. In one embodiment, the method may also include isotropically etching portions of the metallic seed layer 741 that are not covered by the array of metal pillars 749 after removal of the plating matrix layer 747 and prior to formation of the backside molding compound frame 746, wherein the backside molding compound frame 746 may be formed directly on the backside horizontal surface of the first semiconductor die 700. In one embodiment, the backside molding compound frame 746 may be formed directly on a physically exposed planar surface of the metallic seed layer 741, and is vertically spaced from the first semiconductor die 700 by the metallic seed layer 741. In one embodiment, the assembly (700, 741, 742, 746) may be attached to the interposer 400 using an array of first solder material portions 790; and the second semiconductor die 900 may be attached to the interposer 400 using an array of second solder material portions 990. In one embodiment, the method may also include providing a device wafer 70W including the first semiconductor die 700 and additional first semiconductor dies; attaching the device wafer 70W to a carrier wafer such that a backside surface of the device wafer 70W may be physically exposed, wherein the array of metal pillars 749 and arrays of additional metal pillars are attached to the backside surface of the device wafer 70W; forming a molding compound matrix 746 around the array of metal pillars 749 and the arrays of additional metal pillars, wherein the backside molding compound frame 746 comprises a portion of the molding compound matrix; and dicing the device wafer 70W, wherein the assembly is a diced portion of a combination of the device wafer 70W, the array of metal pillars 749 and the arrays of additional metal pillars, and the molding compound matrix 746.

Referring to step 840 and FIG. 3B-3I and 5B-5E, a multi-die molding compound frame 794 may be formed around the assembly {(700, 741, 742, 746) or (700, 741L, 742, 746)} and the second semiconductor die 900.

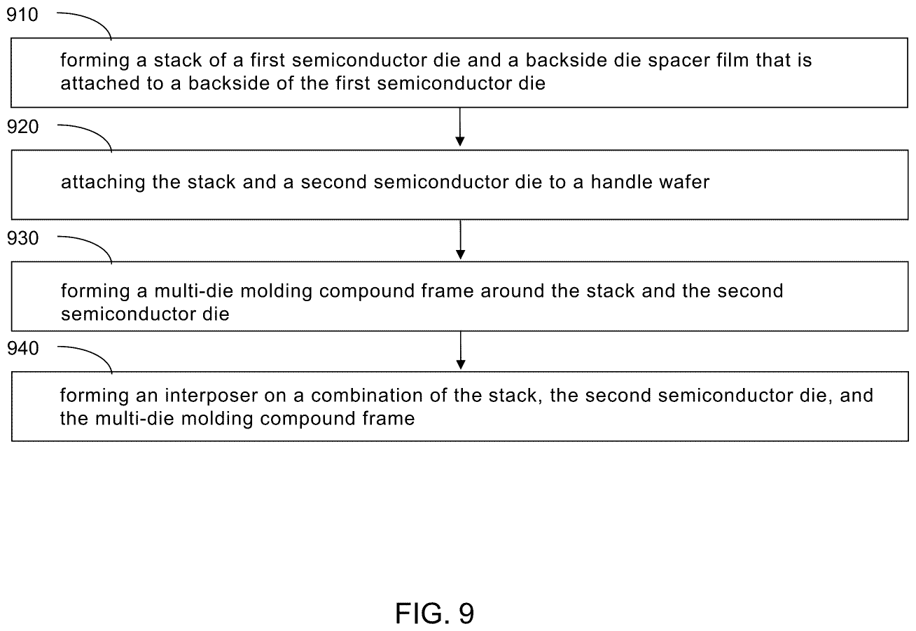

FIG. 9 is a second flowchart illustrating steps for forming a device structure according to an embodiment of the present disclosure.

Referring to step 910 and FIG. 6A-6C, a stack (700, 501) of a first semiconductor die 700 and a backside die spacer film 501 that is attached to a backside of the first semiconductor die 700 may be formed.

Referring to step 920 and FIG. 7A, the stack (700, 501) and a second semiconductor die 900 may be attached to a handle wafer 500.

Referring to step 930 and FIG. 7B, a multi-die molding compound frame 794 may be formed around the stack (700, 501) and the second semiconductor die 900.

Referring to step 940 and FIG. 7C-7L, an interposer 400 may be formed on a combination of the stack, the second semiconductor die 900, and the multi-die molding compound frame 794.

In one embodiment, the method may include the steps of removing the backside die spacer film 501, wherein a distal surface of the second semiconductor die 900 is more distal from the interposer 400 than a distal surface of the first semiconductor die 700 is from the interposer 400. In one embodiment, the stack (700, 501) may be attached to the handle wafer 500 such that the backside die spacer film 501 is more proximal to the handle wafer 500 than the first semiconductor die 700 is to the handle wafer 500. In one embodiment, the method may include applying a molding compound material 794 around the stack (700, 501) and the second semiconductor die 900; and removing a portion of the molding compound material 794 from above a horizontal plane by performing a planarization process, wherein a remaining portion of the molding compound material comprises the multi-die molding compound frame 794. In one embodiment, first metallic pads 778 of the first semiconductor die 700 and second metallic pads 988 of the second semiconductor die 900 may be physically exposed within the horizontal plane after performing the planarization process. In one embodiment, the method may include the steps of forming additional stacks of a respective additional first semiconductor die 700 and a respective additional backside die spacer film 501; attaching the additional stacks and additional second semiconductor dies 900 to the handle wafer 500; forming a molding compound matrix 794 around the stack, the additional stacks, the second semiconductor die 700, and additional semiconductor dies, wherein a combination of the stack, the additional stacks, the second semiconductor die 900, the additional semiconductor dies, and the molding compound matrix 794 comprises a reconstituted wafer 800; forming an interposer array including the interposer 400 and additional interposers on the reconstituted wafer 800; and dicing a combination of the reconstituted wafer 800 and the interposer array.

The various embodiments of the present disclosure provide the advantage of improving thermal dissipation in semiconductor packages by integrating structural components for enhancing thermal management of a semiconductor die such as a first semiconductor die 700. In one embodiment, the metal pillars 742 may be used as thermal antenna structures. The thermal antenna structures enhance heat dissipation by utilizing high thermal conductivity materials such as copper for the metal pillars 742. A metallic seed layer 741L or an array of metallic seed plates 741 may further increase the thermal dissipation. In another embodiment, a combination of a backside die spacer film 501 and a die attachment film 503 may be used to provide a recess cavity 719. In this embodiment, the recess cavity 719 may be formed over the backside surface of the first semiconductor die 700 so that heat dissipation from the first semiconductor die 700 may be enhanced. The at least one opening 229 in the stiffener structure 220 may further increase the heat dissipation from the backside of the first semiconductor die 700. These innovations address the challenges posed by the thickness disparity between multiple semiconductor dies (such as between an SoC die and a DRAM die or a HBM die), thereby ensuring better thermal management, structural integrity, and overall performance of a composite package including multiple semiconductor dies.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a composite package comprising:
forming an array of metal pillars on a backside of a first semiconductor die;
forming a first molding compound frame around the array of metal pillars;
attaching a second semiconductor die and an assembly comprising the first semiconductor die, the array of metal pillars, and the first molding compound frame to an interposer; and
forming a second molding compound frame around the assembly and the second semiconductor die.

2. The method of claim 1, further comprising:
forming a metallic seed layer on a backside surface of the first semiconductor die;
forming a plating matrix layer including an array of pillar-shaped cavities over the metallic seed layer; and
forming the array of metal pillars in the array of pillar-shaped cavities.

3. The method of claim 2, further comprising removing the plating matrix layer selectively to the array of metal pillars and the metallic seed layer, wherein the first molding compound frame is formed directly on the array of metal pillars after removal of the plating matrix layer.

4. The method of claim 3, further comprising isotropically etching portions of the metallic seed layer that are not covered by the array of metal pillars after removal of the plating matrix layer and prior to formation of the first molding compound frame, wherein the first molding compound frame is formed directly on the backside horizontal surface of the first semiconductor die.

5. The method of claim 3, wherein the first molding compound frame is formed directly on a physically exposed planar surface of the metallic seed layer, and is vertically spaced from the first semiconductor die by the metallic seed layer.

6. The method of claim 1, wherein:
the assembly is attached to the interposer using an array of first solder material portions; and
the second semiconductor die is attached to the interposer using an array of second solder material portions.

7. The method of claim 1, further comprising:
providing a device wafer including the first semiconductor die and additional first semiconductor dies;
attaching the device wafer to a carrier wafer such that a backside surface of the device wafer is physically exposed, wherein the array of metal pillars and arrays of additional metal pillars are attached to the backside surface of the device wafer;
forming a molding compound matrix around the array of metal pillars and the arrays of additional metal pillars, wherein the first molding compound frame comprises a portion of the molding compound matrix; and
dicing the device wafer, wherein the assembly is a diced portion of a combination of the device wafer, the array of metal pillars and the arrays of additional metal pillars, and the molding compound matrix.

8. A method of forming a composite package comprising:
forming a stack of a first semiconductor die and a spacer that is attached to a backside of the first semiconductor die;
attaching the stack and a second semiconductor die to a wafer;
forming a multi-die molding compound frame around the stack and the second semiconductor die; and
attaching an interposer on a combination of the stack, the second semiconductor die, and the multi-die molding compound frame.

9. The method of claim 8, further comprising removing the spacer, wherein a distal surface of the second semiconductor die is more distal from the interposer than a distal surface of the first semiconductor die is from the interposer.

10. The method of claim 8, wherein the stack is attached to the handle wafer such that the spacer is more proximal to the handle wafer than the first semiconductor die is to the handle wafer.

11. The method of claim 8, further comprising:
applying a molding compound material around the stack and the second semiconductor die; and
removing a portion of the molding compound material from above a horizontal plane by performing a planarization process, wherein a remaining portion of the molding compound material comprises the multi-die molding compound frame.

12. The method of claim 11, wherein first metallic pads of the first semiconductor die and second metallic pads of the second semiconductor die are physically exposed within the horizontal plane after performing the planarization process.

13. The method of claim 12, further comprising:
forming additional stacks of a respective additional first semiconductor die and a respective additional spacer;
attaching the additional stacks and additional second semiconductor dies to the handle wafer;
forming a molding compound matrix around the stack, the additional stacks, the second semiconductor die, and additional semiconductor dies, wherein a combination of the stack, the additional stacks, the second semiconductor die, the additional semiconductor dies, and the molding compound matrix comprises a reconstituted wafer;
forming an interposer array including the interposer and additional interposers on the reconstituted wafer; and
dicing a combination of the reconstituted wafer and the interposer array.

14. A composite package, comprising:
an interposer;
an assembly that is attached to the interposer and comprising a first semiconductor die, an array of metal pillars located on a backside of the first semiconductor die, and a first molding compound frame laterally surrounding the array of metal pillars;
a second semiconductor die that is attached to the interposer; and
a second molding compound frame laterally surrounding the assembly and the second semiconductor die.

15. The structure of claim 14, further comprising an array of metallic seed plates located between the array of metal pillars and a backside surface of the first semiconductor die.

16. The structure of claim 14, wherein the first molding compound frame is in direct contact with a backside surface of the first semiconductor die.

17. The structure of claim 14, further comprising a metallic seed layer contacting a backside surface of the first semiconductor die and contacting each metal pillar within the array of metal pillars.

18. The structure of claim 14, wherein the first molding compound frame is vertically spaced from the first semiconductor die by a metallic seed layer having a same lateral extent as the first semiconductor die.

19. The structure of claim 14, wherein:
the assembly is attached to the interposer through an array of first solder material portions; and
the second semiconductor die is attached to the interposer through an array of second solder material portions.

20. The structure of claim 14, wherein a vertical distance between a distal surface of the second semiconductor die and the interposer is less than a vertical distance between distal end surfaces of the metal pillars and the interposer, and is greater than a vertical distance between a distal surface of the first semiconductor die and the interposer.
